(19) United States
(12) Patent Application Publication
(10) Pub. No.: US 2026/0073101 A1
(43) Pub. Date: Mar. 12, 2026

(54) DETERMINING A STATUS OF A BUILT ENVIRONMENT USING A GRAPH NEURAL NETWORK (GNN)

(71) Applicant: Field AI, Inc., Mission Viejo, CA (US)

(72) Inventor: Navid KAYHANI, Toronto (CA)

(73) Assignee: Field AI, Inc., Mission Viejo, CA (US)

(21) Appl. No.: 19/325,620

(22) Filed: Sep. 11, 2025

Related U.S. Application Data
(60) Provisional application No. 63/693,832, filed on Sep. 12, 2024.

(51) Int. Cl. G06F 30/27; G06F 30/13

(52) U.S. Cl. CPC G06F 30/27; G06F 30/13

(57) ABSTRACT

Systems and methods for determining a status of a built environment using a graph neural network are provided. An example system may obtain build data including a building information model (BIM) of the built environment, scan data depicting the built environment, and scheduling data indicating tasks for constructing the built environment. The system may perform a registration of the scan data and build data, and generate BIM-based features indicating hierarchical relationships of elements of the BIM, scan-based features indicating characteristics of scans of the built environment, and scheduling-based features indicating characteristics of the built tasks. The system may provide the build data, the BIM-based features, the scan data, the scan-based features, the scheduling data, and the scheduling-based features to a temporal graph neural network to generate a graph, and the status of the built environment based upon the graph. The system may provide the built status to a computing device.

### CROSS-REFERENCE TO RELATED APPLICATION

This application claims priority to and the benefit of the filing date of provisional U.S. Patent Application No. 63/693,832, entitled “SYSTEM AND METHOD FOR REAL-TIME MONITORING OF BUILT ENVIRONMENTS USING GRAPH NEURAL NETWORKS (GNN) MODEL” and filed on Sep. 12, 2024, the entire contents of which is hereby expressly incorporated herein by reference.

### TECHNICAL FIELD

The implementations of the present disclosure relate to assessing construction quality, and specifically to a system and method for determining a status of a built environment using a graph neural network.

### BACKGROUND

Construction quality control is a critical aspect of an architecture, engineering, and construction (AEC) industry. Ensuring that built environments (e.g., floors, wall, windows, and/or other infrastructure) are constructed according to design specifications is essential for safety, functionality, and compliance with regulations. Traditional methods of construction quality assessment rely on manual inspections, which may be time-consuming, labor-intensive, and prone to human error.

The adoption of build data including Building Information Models (BIM) has revolutionized the AEC industry by providing detailed digital representations of physical characteristics and functional characteristics of built environments. The BIM has enabled improved collaboration, visualization, and planning throughout the construction process of built environments. However, leveraging the build data for automated construction quality control remains a challenge, particularly when dealing with complexities of real-world built environments.

As built environments are generally dynamic environments, various factors impact data collection and analysis. Sensor noise, weather conditions, lighting variations, material properties (e.g., reflectivity), occlusions (e.g., obstacles), and presence of dynamic objects may all affect the quality and completeness of data capturing the built environment, such as point cloud data. This results in partial observability of physical components of a built environment associated with building elements of the BIM, making it difficult to perform the comprehensive construction quality assessments of the built environments. Furthermore, isolated analysis of the physical components, without considering their semantic relationships and context within the overall built environment, may lead to incomplete and inaccurate construction quality assessments. The tasks involved in constructing the built environment involve complex interdependencies between different components, and understanding these relationships is crucial for the effective construction quality control.

As the AEC industry continues to evolve and embrace digital technologies, there is a growing need for advanced systems that may overcome the limitations of traditional quality control methods. Such systems should be capable of handling incomplete data, incorporating semantic information, and leveraging the rich context provided by the build data and other types of data (e.g., scan data from imaging the built environment, scheduling data associated with construction of the built environment) to perform more accurate and comprehensive construction quality assessments. Therefore, there is a need for innovative approaches that address the aforementioned short-comings and disadvantages of determining the status of a built environment.

### SUMMARY

In one general aspect, the instant disclosure describes a computer-implemented method for determining a status of a built environment using a graph neural network. The computer-implemented method may include obtaining, by one or more processors: build data including a building information model (BIM) of the built environment, wherein the BIM includes a plurality of elements corresponding to a plurality of physical components of the built environment, and an Industry Foundation Classes (IFC) schema indicating hierarchical relationships between the plurality of elements; scan data generated via an imaging device during one or more scans by imaging at least a portion of the plurality of physical components of at least a portion of the built environment, wherein: at least one physical component of at least the portion of the built environment is not fully captured by the scan data due to data incompleteness, and the scan data indicates for each of the one or more scans a pose of the imaging device and timestamp information; and scheduling data indicating a plurality of built tasks associated with constructing the built environment; performing, by the one or more processors, a registration of the scan data with the build data to generate a correspondence between the plurality of physical components of the scan data and a respective at least some elements of the plurality of elements of the build data; generating, by the one or more processors: BIM-based features indicating hierarchical relationships of the plurality of elements based upon semantics of the IFC schema of the build data; scan-based features indicating characteristics of the one or more scans; and scheduling-based features indicating characteristics associated with performing each of the plurality of built tasks based upon the scheduling data; providing, by the one or more processors, the build data, the BIM-based features, the scan data, the scan-based features, the scheduling data, and the scheduling-based features as an input to a temporal graph neural network (TGNN), causing the TGNN to: generate a graph having: a plurality of nodes including: a plurality of element nodes each corresponding to one element of the plurality of elements, a plurality of task nodes each corresponding to one built task of the plurality of built tasks, and a plurality of scan nodes each corresponding to one scan of the one or more scans; a plurality of edges each connecting two nodes and each corresponding to relationship between the two nodes, wherein at least one relationship of the graph indicates a temporal relationship; one or more features applied to the plurality of nodes based upon the BIM-based features, the scan-based features, the schedule-based features, or graph-based features based up relationships of local neighborhoods of the plurality of nodes of the graph, wherein: each feature applied to an element node indicates a feature of the corresponding element, each feature applied to a task node indicates a feature of the corresponding built task, and each feature applied to a scan node indicates a feature of the corresponding scan; and one or more attributes applied to the plurality of edges, each attribute indicating an attribute of the corresponding relationship; and in response to generating the graph, generate built status data indicating the status of the built environment based upon analyzing the graph; and providing, by the one or more processors, the built status data to a computing device.

In another general aspect, the instant disclosure describes a system for determining a status of a built environment using a graph neural network. The system may include one or more processors; and one or more memories having stored thereon processor-executable instructions that, when executed by the one or more processors, cause the one or more processors to: obtain: build data including a building information model (BIM) of the built environment, wherein the BIM includes a plurality of elements corresponding to a plurality of physical components of the built environment, and an Industry Foundation Classes (IFC) schema indicating hierarchical relationships between the plurality of elements; scan data generated via an imaging device during one or more scans by imaging at least a portion of the plurality of physical components of at least a portion of the built environment, wherein: at least one physical component of at least the portion of the built environment is not fully captured by the scan data due to data incompleteness, and the scan data indicates for each of the one or more scans a pose of the imaging device and timestamp information; and scheduling data indicating a plurality of built tasks associated with constructing the built environment; perform a registration of the scan data with the build data to generate a correspondence between the plurality of physical components of the scan data and a respective at least some elements of the plurality of elements of the build data; generate: BIM-based features indicating hierarchical relationships of the plurality of elements based upon semantics of the IFC schema of the build data; scan-based features indicating characteristics of the one or more scans; and scheduling-based features indicating characteristics associated with performing each of the plurality of built tasks based upon the scheduling data; provide the build data, the BIM-based features, the scan data, the scan-based features, the scheduling data, and the scheduling-based features as an input to a temporal graph neural network (TGNN), causing the TGNN to: generate a graph having: a plurality of nodes including: a plurality of element nodes each corresponding to one element of the plurality of elements, a plurality of task nodes each corresponding to one built task of the plurality of built tasks, and a plurality of scan nodes each corresponding to one scan of the one or more scans; a plurality of edges each connecting two nodes and each corresponding to relationship between the two nodes, wherein at least one relationship of the graph indicates a temporal relationship; one or more features applied to the plurality of nodes based upon the BIM-based features, the scan-based features, the schedule-based features, or graph-based features based up relationships of local neighborhoods of the plurality of nodes of the graph, wherein: each feature applied to an element node indicates a feature of the corresponding element, each feature applied to a task node indicates a feature of the corresponding built task, and each feature applied to a scan node indicates a feature of the corresponding scan; and one or more attributes applied to the plurality of edges, each attribute indicating an attribute of the corresponding relationship; and in response to generating the graph, generate built status data indicating the status of the built environment based upon analyzing the graph; and provide the built status data to a computing device.

In another general aspect, the instant disclosure describes a non-transitory computer-readable medium storing processor-executable instructions that, when executed by one or more processors, may cause the one or more processors to at least: obtain: build data including a building information model (BIM) of a built environment, wherein the BIM includes a plurality of elements corresponding to a plurality of physical components of the built environment, and an Industry Foundation Classes (IFC) schema indicating hierarchical relationships between the plurality of elements; scan data generated via an imaging device during one or more scans by imaging at least a portion of the plurality of physical components of at least a portion of the built environment, wherein: at least one physical component of at least the portion of the built environment is not fully captured by the scan data due to data incompleteness, and the scan data indicates for each of the one or more scans a pose of the imaging device and timestamp information; and scheduling data indicating a plurality of built tasks associated with constructing the built environment; perform a registration of the scan data with the build data to generate a correspondence between the plurality of physical components of the scan data and a respective at least some elements of the plurality of elements of the build data; generate: BIM-based features indicating hierarchical relationships of the plurality of elements based upon semantics of the IFC schema of the build data; scan-based features indicating characteristics of the one or more scans; and scheduling-based features indicating characteristics associated with performing each of the plurality of built tasks based upon the scheduling data; provide the build data, the BIM-based features, the scan data, the scan-based features, the scheduling data, and the scheduling-based features as an input to a temporal graph neural network (TGNN), causing the TGNN to: generate a graph having: a plurality of nodes including: a plurality of element nodes each corresponding to one element of the plurality of elements, a plurality of task nodes each corresponding to one built task of the plurality of built tasks, and a plurality of scan nodes each corresponding to one scan of the one or more scans; a plurality of edges each connecting two nodes and each corresponding to relationship between the two nodes, wherein at least one relationship of the graph indicates a temporal relationship; one or more features applied to the plurality of nodes based upon the BIM-based features, the scan-based features, the schedule-based features, or graph-based features based up relationships of local neighborhoods of the plurality of nodes of the graph, wherein: each feature applied to an element node indicates a feature of the corresponding element, each feature applied to a task node indicates a feature of the corresponding built task, and each feature applied to a scan node indicates a feature of the corresponding scan; and one or more attributes applied to the plurality of edges, each attribute indicating an attribute of the corresponding relationship; and in response to generating the graph, generate built status data indicating a status of the built environment based upon analyzing the graph; and provide the built status data to a computing device.

### BRIEF DESCRIPTION OF THE DRAWINGS

The drawing figures depict one or more implementations in accord with the present teachings, by way of example only, not by way of limitation. In the figures, like reference numerals refer to the same or similar elements. Furthermore, it should be understood that the drawings are not necessarily to scale.

FIG. 1 is a block diagram depicting an example computing environment for determining the status of a built environment, in one implementation of the instant application.

FIG. 2 is a block diagram depicting an example training process of a machine learning model in one implementation of the instant application.

FIG. 3A is a block diagram of an exemplary workflow for determining the status of a built environment, in one implementation of the instant application.

FIG. 3B depicts an example build information model of a built environment, in one implementation of the instant application.

FIG. 3C depicts a block diagram of an example tree generated by an IFC2VEC model, in one implementation of the instant application.

FIG. 3D depicts a set of images associated with a built environment, in one implementation of the instant application.

FIG. 3E depicts an example set of images of example topical and spatial relationships of build information model elements, in one implementation of the instant application.

FIG. 3F is a block diagram of a portion of an example graph, in one implementation of the instant application.

FIG. 3G is a block diagram of an example architecture of a temporal graph neural network, in one implementation of the instant application.

FIG. 3H is a block diagram of a workflow for performing discrete-event simulation, in one implementation of the instant application.

FIG. 3I is a block diagram of a workflow for performing multi-scan evidence fusion, in one implementation of the instant application.

FIG. 3J is a block diagram of a workflow for performing differentiable relation discovery, in one implementation of the instant application.

FIG. 4 is a flow diagram depicting an example computer-implemented method for determining a status of a built environment using a graph neural network, in one implementation of the instant application.

### DETAILED DESCRIPTION

In the following detailed description, numerous specific details are set forth by way of examples in order to provide a thorough understanding of the relevant teachings. It will be apparent to persons of ordinary skill, upon reading this description, that various aspects can be practiced without such details. In other instances, well-known methods, procedures, components, and/or circuitry have been described at a relatively high-level, without detail, in order to avoid unnecessarily obscuring aspects of the present teachings.

The disclosed systems and methods determine a status of a built environment using a graph neural network (GNN). An example system may obtain various type of data associated with the built environment, such as build data, scan data, and scheduling data. The build data may include a building information model (BIM) of the built environment. The BIM may include elements of the modeled built environment that corresponding to physical components of the real-world built environment, as well as Industry Foundation Classes (IFC) schema indicating hierarchical relationships between the elements of the BIM. The scan data may be generated by one or more imaging devices at one or more times by scanning or otherwise imaging at least a portion of the physical components of the built environment, for example to depict a temporal build status. At least one physical component of the built environment may not be captured by the scan data due to data incompleteness (e.g., a characteristic of the imaging device, an environmental conditions during the scans, a characteristics of the physical component occlusion of the physical component, etc.) which using conventional build status techniques may cause the uncaptured physical component to have an unknown build status. The scheduling data may indicate information associated with built for constructing the built environment (e.g., assigned work crew, expected built task start or completion time, slack (e.g., allowable task delay), built task precedence, etc.

The system may perform a registration to align the scan data with the build data and generate correspondences between the physical components and corresponding digital elements. The system may generate features for each of the build, scan, and scheduling data. The BIM-based features of the build data may indicate hierarchical relationships of the elements based upon semantics of the IFC schema of the build data. The scan-based features may indicate characteristics of the scans. The scheduling-based features may indicate characteristics associated with performing the built tasks.

A temporal graph neural network (TGNN) may generate a graph based upon receiving the build data, the BIM-based features, the scan data, the scan-based features, the scheduling data, and the scheduling-based features as inputs. The graph may include nodes each representing a scan, a built task, or an element. The nodes may be connected by edges representing relationships between the nodes, and at least one relationship of the graph may be temporal in nature. The TGNN may apply features to the nodes and attributes to the edges based upon the BIM-based features, the scan-based features, the scheduling-based features, as well as graph-based features that are generated based upon relationships of local neighborhoods of the nodes. In response to generating the graph, the TGNN may generate built status data indicating the status of the built environment based upon analyzing the graph, and provide the built status data to a computing device (e.g., for user review, feedback, an/or otherwise analysis). The built status data may include reports, visualizations, multimedia, summarize the status of the construction, outline issues, provide suggestions for corrective actions, or provide other information serving as valuable resource for project documentation and decision-making.

The disclosed systems and methods address the aforementioned shortcomings of conventional built environment status-determining systems and technologies by providing assessments of built environments that compensate for sensor noise, weather conditions, lighting variations, material properties, occlusions, and/or other sources of data incompleteness. The disclosed system and methods can make inferences and/or other determinations about elements depicted in the BIM that may not be detected in the scan data due to data incompleteness. For example, a door located in a wall may be mostly occluded due to obstacles in front of the door and lying against the wall during imaging, however, the door handle and panes of glass in the door may be captured during a scan indicating the door is in fact set in a wall. The TGNN may be able to detect such associations and otherwise semantic relationships to provide an accurate status of the construction status of the door. Moreover, the system is able to process new data as it is received via the TGNN, such new scan data depicting real-time updates on the construction progress of a built environment or revised scheduling data with updated built task schedules. Based upon the updated data, the system can provide real-time updates to the graph (e.g., add, remove, and/or edit edges, nodes, edge attributes, and/or node features) and similarly provide real-time updates to the built environment status generated from the updated graph, thereby providing rapid and accurate information on built status not available using conventional systems. Further, the system can process temporal data, such as bult task schedules to understand when a construction project may be falling behind, and in response generate suggestions for getting the construction back on track.

The disclosed techniques improve the operation of built environment status systems. As previously mentioned, the system is able to ingest multiple types of disparate data in real-time, reconcile the data via registrations, and understand semantic relationship through the generation of unique graph types with particular nodes representing tasks, scans and elements along with edges indicating their relationships. Moreover, the graph is augmented with attributes and features providing a granular level of detail for each element, task, and node that is unmatched by conventional systems. Further, the disclosed system includes a particularly trained TGNN that is able to process BIMs, IFC schema, scan data, scheduling data, BIM-based features, scan-based features, scheduling-based features and graph-based features to generate a dynamic four-dimensional spatio-temporal graph where edges may appear, disappear, and/or the graphs may otherwise be dynamically reconfigured over time. Accordingly, the disclosed techniques do not simply apply existing models in new data environments, but rather generate new models through a detailed training process. Along these lines, the TGNN may act in concert IFC2VEC and BIM2GRAPH models to perform various steps of the disclosed techniques, providing a unique ensemble of models having a particular data flow that improves the technology of built environment status assessment. Additionally, the system may perform multi-scan evidence fusion to combine, integrate, and/or otherwise process information from multiple scans of the built environment of the same target or scene to achieve a more reliable outcome. This is especially useful in systems where sensors may be unreliable or produce conflicting data points.

In another example, the disclosed techniques may provide improvement of the disclosed system over time. For example, the system may retrain one or more of the models based upon updated information, such as updated scheduling and/or scan information, to improve its ability to make association or otherwise understand new semantic relationships, to continuously improve the performance of the system in generating built status data. Accordingly, the disclosed system may provide improvement functionality compared to conventional systems without such capabilities.

In sum, the disclosed system and methods provide improvements to systems, technologies and the overall technical field for determining a status of a built environment respective to conventional techniques which suffer from deficient performance in dynamic built environments where semantic relationships and context within the built environment go undetected and lead to incomplete and inaccurate construction quality assessments. Rather, the disclosed system and methods are proficient in dynamic environments, can improve overtime, and provide quality construction assessments when handling data incompleteness, among other things.

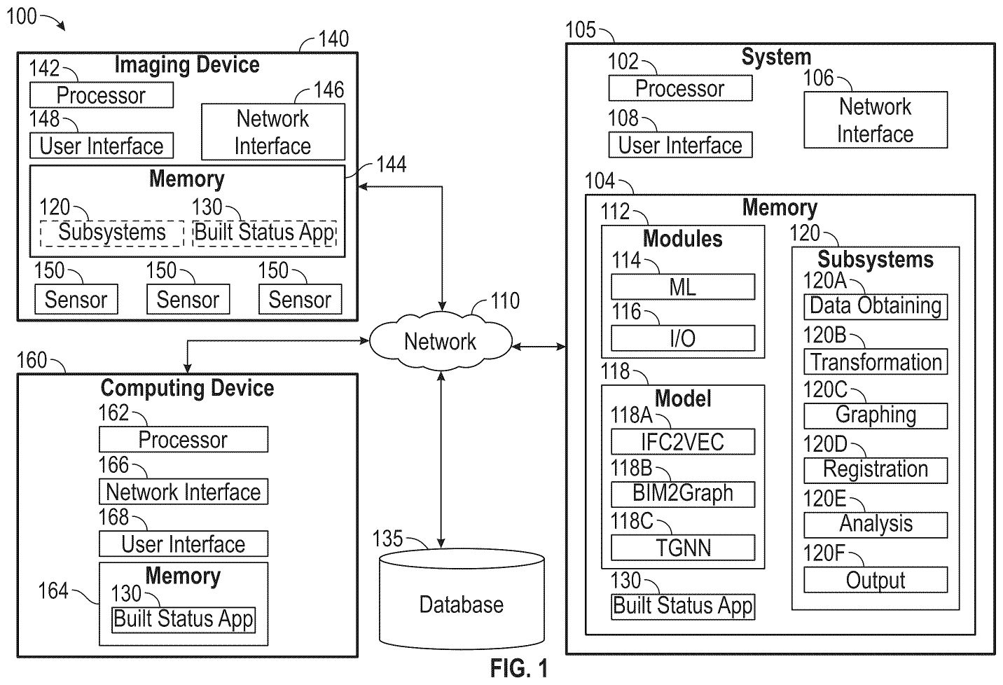

FIG. 1 is a block diagram depicting an example computing environment 100 for determining the status of a built environment, in one implementation of the instant application. The computing environment 100 may include a system 105 communicatively coupled, via a network 110, to a database 135, an imaging device 140, and a computing device 160. Although FIG. 1 depicts certain entities, components, equipment, and devices, it should be appreciated that fewer, additional and/or alternate entities, components, equipment, and/or devices may be envisioned.

The system 105 may perform functionalities associated with determining a status of a built environment, such obtaining data associated with the built environment (e.g., build data, scan data, scheduling data), generating a graph representing the built environment, generating status data indicating the built environment status, etc. The system 105 may include, and or be part of, a cloud network or may otherwise communicate with other hardware or software components within one or more cloud computing environments to send, retrieve, or otherwise analyze data or information described herein. For example, in certain aspects of the present techniques, the computing environment 100 may include an on-premise computing environment, a multi-cloud computing environment, a public cloud computing environment, a private cloud computing environment, and/or a hybrid cloud computing environment. For example, an entity (e.g., a robotics company) may host one or more services in a public cloud computing environment (e.g., Alibaba Cloud®, Amazon Web Services® (AWS), Google Cloud®, IBM Cloud®, Microsoft Azure®, etc.). The public cloud computing environment may be a traditional off-premise cloud (i.e., not physically hosted at a location owned/controlled by the entity). Alternatively, or in addition, aspects of the public cloud may be hosted on-premises at a location owned/controlled by the entity. The public cloud may be partitioned using visualization and multi-tenancy techniques and may include one or more infrastructure-as-a-service (IaaS) and/or platform-as-a-service (PaaS) services.

The system 105 may include at least one processor 102. The processor 102 may include one or more computational circuits, including, but not limited to, one or more central processing units (CPUs), microprocessor units, microcontrollers, complex instruction set computing (CISC) microprocessor units, reduced instruction set computing microprocessor (RISC) units, very long instruction word microprocessor units, explicitly parallel instruction computing microprocessor units, graphics processing units (GPUs), digital signal processing (DPS) units, or any other type of processing circuit. The processor 102 may also include embedded controllers, such as generic or programmable logic devices or arrays, application-specific integrated circuits (ASICs), single-chip computers, and the like. The processor 102 may be connected to a memory 104 via a computer bus (not depicted) responsible for transmitting electronic data, data packets, and/or otherwise electronic signals to and from the processor 102 and a memory 104 in order to implement or perform the machine-readable instructions, methods, processes, elements, or limitations, as illustrated, depicted, or described for the various flowcharts, illustrations, diagrams, figures, and/or other disclosure herein. The processor 102 may interface with the memory 104 via a computer bus to execute an operating system and/or computing instructions contained therein, and/or to access other services/aspects. For example, the processor 102 may interface with the memory 104 via the computer bus to create, read, update, delete, or otherwise access or interact with the data stored in the memory 104 and/or the database 135.

The system 105 may include at least one network interface 106. The network interface 106 may allow the system 105 to communicate over the network 110, for example via any suitable wired and/or wireless connection. The network interface 106 may include one or more hardware, firmware, and/or software components (e.g., Ethernet cards, Wi-Fi adapters, cellular modems). The network interface 106 may include one or more transceivers (e.g., wireless wide area network (WWAN), wireless local area network WLAN, and/or wireless personal area network (WPAN) transceivers) functioning in accordance with IEEE® standards, 3GPP® standards, and/or other standards, and that may be used in receipt and transmission of data (e.g., via external/network ports connected to the network 110).

The system may include at least one user interface 108. The user interface 108 may include one or more components and/or devices to receive an input and/or generate an output. The user interface 108 may include one or more of a keyboard, a mouse, a display (e.g., liquid crystal display (LCD), organic light-emitting diode (OLED) display), a touchscreen, a microphone, a speaker, an imaging device, a button, a switch, and/or other suitable components or device for to receiving an input and/or generating an output.

The memory 104 may include one or more forms of volatile and/or non-volatile, fixed and/or removable memory, such as read-only memory (ROM), electronic programmable read-only memory (EPROM), random access memory (RAM), erasable electronic programmable read-only memory (EEPROM), compact disks, digital video disks, diskettes, magnetic tape cartridges and/or other hard drives, flash memory, MicroSD® cards, and others. The memory 104 may store an operating system (e.g., Microsoft Windows®, Linux®, UNIX®, etc.) capable of facilitating the functionalities, apps, methods, or other software as discussed herein. In general, a computer program or computer based product, application, or code (e.g., ML models or other computing instructions described herein) may be stored on a machine-readable storage medium, or tangible, non-transitory computer-readable medium (e.g., standard random access memory (RAM), an optical disc, a universal serial bus (USB) drive, or the like) having such computer-readable program code or computer instructions embodied therein, wherein the computer-readable program code or computer instructions may be installed on or otherwise adapted to be executed by the processor 102 (e.g., working in connection with the respective operating system in memory 104) to facilitate, implement, or perform the machine readable instructions, methods, processes, elements or limitations, as illustrated, depicted, or described for the various flowcharts, illustrations, diagrams, figures, and/or other disclosure herein. In this regard, the program code may be implemented in any desired program language, and may be implemented as machine code, assembly code, byte code, interpretable source code or the like (e.g., via Golang®, Python®, C®, C++ R, C #®, Objective-CR, Java®, Scala®, ActionScript®, JavaScript®, HTML®, CSS®, XML®, etc.).

The memory 104 may store at least one computing module 112. The computing module 112 may be implemented as respective sets of computer-executable instructions (e.g., one or more source code libraries) as described herein. A component or device (standalone, client or distributed computer or computing system) configured by an application may constitute a computing module 112, also referred to herein at times interchangeably as a “subsystem” or “module,” that is configured and operated to perform certain operations. In one implementation, the computing module 112 may be implemented mechanically or electronically. The computing module 112 may include dedicated circuitry or logic that is permanently configured (within a special-purpose processor) to perform certain operations. In another implementation, the computing module 112 may also include programmable logic or circuitry (as encompassed within a general-purpose processor or other programmable processor) that is temporarily configured by software to perform certain operations. Accordingly, the term computing module 112 should be understood to encompass a tangible entity, be that an entity that is physically constructed permanently configured (hardwired) or temporarily configured (programmed) to operate in a certain manner and/or to perform certain operations described herein.

The computing module 112 may include an ML module 114. The ML module 114 may perform ML model training and/or operation. In at least some implementations, at least one of a plurality of ML methods and algorithms may be applied by the ML module 114, which may include, but are not limited to: linear or logistic regression, instance-based algorithms, regularization algorithms, decision trees, Bayesian networks, cluster analysis, association rule learning, artificial neural networks, deep learning, combined learning, reinforced learning, dimensionality reduction, and support vector machines. In various implementations, the implemented ML methods and algorithms are directed toward at least one of a plurality of categorizations of ML, such as supervised learning, unsupervised learning, and reinforcement learning. In one aspect, the ML based algorithms may be included as a library or package executed on the system 105. For example, libraries may include the TensorFlow® based library, the PyTorch® library, and/or the scikit-learn Python® library.

In one implementation, the ML module 114 employs supervised learning, which involves identifying patterns in existing data to make predictions about subsequently received data. Specifically, the ML module 114 is “trained” using training data, which includes exemplary inputs and associated exemplary outputs. Based upon the training data, the ML module 114 may generate a predictive function which maps outputs to inputs and may utilize the predictive function to generate ML outputs based upon data inputs. The exemplary inputs and exemplary outputs of the training data may include any of the data inputs or ML outputs described above. In the exemplary implementations, a processing element may be trained by providing it with a large sample of data with known characteristics or features.

In another implementation, the ML module 114 may employ unsupervised learning, which involves finding meaningful relationships in unorganized data. Unlike supervised learning, unsupervised learning does not involve user-initiated training based upon exemplary inputs with associated outputs. Rather, in unsupervised learning, the ML module 114 may organize unlabeled data according to a relationship determined by at least one ML method/algorithm employed by the ML module 114. Unorganized data may include any combination of data inputs and/or ML outputs as described above.

In yet another implementation, the ML module 114 may employ reinforcement learning, which involves optimizing outputs based upon feedback from a reward signal. Specifically, the ML module 114 may receive a user-defined reward signal definition, receive a data input, utilize a decision-making model to generate the ML output based upon the data input, receive a reward signal based upon the reward signal definition and the ML output, and alter the decision-making model so as to receive a stronger reward signal for subsequently generated ML outputs. Other types of ML may also be employed, including deep or combined learning techniques.

The ML module 114 may include a set of computer-executable instructions implementing ML training (e.g., model creation, fine-tuning, retraining, etc.). The ML module 114 may access one or more repositories (e.g., the database 135) or any other data source for training data suitable to generate and/or otherwise train one or more ML models. The training data may be sample data with assigned relevant and comprehensive labels (classes or tags) used to fit the parameters (weights) of an ML model with the goal of training it by example. In one aspect, once an appropriate ML model is trained and validated to provide accurate predictions and/or responses, the trained model may be loaded into ML module 114 at runtime to process input data and generate output data.

The ML module 114 may receive labeled data at an input layer of a model having a networked layer architecture (e.g., an artificial neural network, a convolutional neural network, etc.) for training the one or more ML models. The received data may be propagated through one or more connected deep layers of the ML model to establish weights of one or more nodes, or neurons, of the respective layers. Initially, the weights may be initialized to random values, and one or more suitable activation functions may be chosen for the training process. The present techniques may include training a respective output layer of the one or more ML models. The output layer may be trained to output a prediction, for example.

The ML module 114 may include a set of computer-executable instructions implementing ML loading, configuration, initialization and/or operation functionality. The ML module 114 may include instructions for storing trained models (e.g., in the database 135). As discussed, once trained, the one or more trained ML models may be operated in inference mode, whereupon when provided with de novo input that the model has not previously been provided, the model may output one or more predictions, classifications, etc., as described herein.

While various implementations, examples, and/or aspects disclosed herein may include training and generating one or more ML models for the system 105 to load at runtime, it is also contemplated that one or more appropriately trained ML models may already exist (e.g., stored in the database 135, the computing device 160) such that the system 105 may load an existing trained ML model at runtime. It is further contemplated that the system 105 may retrain, fine-tune, update and/or otherwise alter an existing ML model before and/or after loading the model at runtime. Accordingly, one device (e.g., the system 105) of the computing environment 100 may train the ML model while another device (e.g., the computing device 160) may execute the ML model.

The computing module 112 may include an input/output (I/O) module 116, including a set of computer-executable instructions implementing communication functions. The I/O module 116 may include a communication component configured to communicate (e.g., send and receive) data via one or more external/network port(s) to one or more components (e.g., the user interface 108), networks (e.g., the network 110) devices (e.g., the imaging device 140 and/or the computing device 160) as described herein. I/O module 116 may further include or implement an operator interface configured to present information to an administrator or operator and/or receive inputs from the administrator and/or operator (e.g., via the user interface 108). The I/O module 116 may facilitate I/O components (e.g., ports, capacitive or resistive touch sensitive input panels, keys, buttons, lights, LEDs), which may be directly accessible via, or attached to, the system 105 or may be indirectly accessible via or attached to another device (e.g., the computing device 160).

The memory 104 may include at least one model 118. The model may include a routine ML model, or other element stored in memory 104 may be referred to as receiving an input, producing or storing an output, or executing, the routine, model, or other element. The model 118 may be executing as instructions on the processor 102. Further, those of skill in the art will appreciate that the model 118 be stored in the memory 104 as executable instructions, which instructions the processor 102 may retrieve from the memory 104 and execute. Further, the processor 102 should be understood to retrieve from the memory 104 any data necessary to perform the executed instructions (e.g., data required as an input to model 118), and to store in the memory 104 the intermediate results and/or output of any executed instructions.

The model 118 may include an IFC2VEC model 118A configured to receive build data as an input, and in response generate an output indicating features of the elements indicated by the build data, the features referred to herein at times as “BIM-based features.” The BIM-based features may be based upon learned semantics of the hierarchical relationships of the elements indicated in the IFC schema of the build data. The output of the IFC2VEC model 118A may include one or more vectors encoding the BIM-based features.

The model 118 may include an BIM2GRAPH model 118B configured to receive build data as an input. In response to receiving the build data, the BIM2GRAPH model 118B may generate a graph representing the built environment. The graph may include a plurality of element node corresponding to the element of the BIM data. The graph may include a plurality of edges. Each edge may connect two nodes and correspond to a relationship between the two connected nodes. At least one of the relationships of the graph may indicate a temporal relationship.

The model 118 may include a TGNN model 118C configured to generate a graph that may be, and/or include, a dynamic four-dimensional (4D) spatio-temporal graph. For example, the graph of the TGNN model 118C may build upon a static graph generated by the BIM2GRAPH model 118B where all the nodes correspond to elements, or generate an entirely new graph. The graph may be generated based upon the build data, the BIM-based features, the scan data, the scan-based features, the scheduling data, the scheduling-based features and/or the graph-based features. The nodes of the graph may correspond to elements, scans, and built tasks, and have one or more temporal aspects. The TGNN model 118C may generate built status data indicating the status of the built environment based upon analyzing the graph. For example, the TGNN model 118C may generate classifications associated with the built status (e.g., classification of elements), schedule performance of built tasks (e.g., classification of built task and timing data of the scheduling data), and/or other suitable classifications based upon information indicted in the augmented graph. Generating the built status data may include classifying each of the elements of the built environment with a classification selected from the group consisting of verified, deviated, missing, and no data. Generating the built status data may include performing discrete-event simulation to identify one or more of a risk, a delay, or a critical path of the graph associated with the built environment.

The memory 104 may include one or more subsystems 120. The subsystems 120 may include a data-obtaining subsystem 120A, a transformation subsystem 120B, a graphing subsystem 120C, an alignment subsystem 120D, an analysis subsystem 120E, and an output subsystem 120F.

The data-obtaining subsystem 120A may be configured to obtain one or more types of data associated with determining the status of a built environment, such as build data, scan data, scheduling data, and/or any other suitable data. The data-obtaining subsystem 120A may obtain the one or more types of data from memory (e.g., the memory 104), from another component and/or device of the computing environment 100 (e.g., the database 135, the imaging device 140, and/or the computing device 160 via the network 110), and/or any other suitable source of data. For example, the data-obtaining subsystem 120A may obtain scan data from the imaging device 140.

The data-obtaining subsystem 120A may be configured to integrate data from one or more data sources. Each of the data sources may provide data imaging the built environment from different perspectives, using different imaging modalities, at different points in time, etc., to collectively provide a more comprehensive view of the built environment than one data source alone. In one example, the imaging device 140 may perform a first scan by imaging the built environment at a first point in time to generate a first scan dataset, and then perform a second scan by imaging the built environment at a second point in time to generate a second scan dataset. The data-obtaining subsystem 120A may generate the scan data by integrating the first scan dataset and the second scan dataset. In a second example, a first imaging device 140 may perform a first scan by imaging the built environment using a LIDAR sensor to generate point cloud data of the built environment, and a second imaging device 140 may perform a second scan by imaging the built environment using a CMOS sensor to generate video of the built environment. The data-obtaining subsystem 120A may generate scan data that includes the point-cloud data and the video data.

The build data may be, or include a BIM which may depict a model of the built environment. The BIM may include elements (e.g., digital elements) corresponding physical components (e.g., walls, floors, pipes, electrical wiring, etc.) of the built environment. The BIM may include the IFC schema that indicates hierarchical relationships between the elements. The IFC schema may include a hierarchical class structure where each class has associations with others, for example, the IFC schema may indicate a wall contains a window and a door, electrical wiring runs through a junction box, etc. The IFC schema may include child classes that inherit properties of their parent classes. The scan data may include data generated from one or more imaging modalities, such as images (e.g., two-dimensional, three-dimensional), video, light detection and ranging (LIDAR), radio detection and ranging (RADAR), infrared (IR), x-ray, and/or any other suitable imaging modality. The scheduling data may indicate information associated with a schedule for building the built environment, such as information indicating one or more of built tasks (e.g., constructions tasks), labor for performing the built tasks, the start, duration, end, and/or slack associated with performing the built tasks, the physical components associated with performing the built tasks, and/or other suitable scheduling information.

The transformation subsystem 120B may be configured to extract information associated with determining the status of the built environment form one or more data sources. For example, the transformation subsystem 120B may extract locations and specifications (e.g., size, shape, material, tolerances) of elements (e.g., walls, doors, windows) from the build data, schedules of built tasks from the scheduling data, timestamp information from the scan data, etc. This transformation subsystem 120B may ensure one or more types of information relevant to determining the build status is provided to, and/or otherwise identified by, the system 105.

The graphing subsystem 120C may be configured to receive one or more types of information (e.g., information the extracted by the transformation subsystem 120B) and in response generate a graph, such as a dynamic four-dimensional spatio-temporal graph, associated with the status of the built environment. For example, based upon receiving the build data, the scan data, and the scheduling data, the graphing subsystem 120C may generate a graph including nodes representing building elements, built tasks and scans of the built environment. The graph edges represent relationships between nodes including topological relationships (e.g., how the building elements are connected), temporal relationships (e.g., construction sequences), and spatial relationships (e.g., physical locations of elements). The nodes may be associated with features (e.g., indicating the size, shape, and tolerances of an element corresponding to an element node) and the edges may be associated with attributes (e.g., indicating the temporal order of performing built tasks corresponding to task nodes connected by the edge). The graphing subsystem 120C may allow the system 105 to understand (e.g., via the graph) the status of the built project based upon logical, spatial, temporal characteristics, facilitating more accurate and advanced analysis and quality assessment of a built project than convention systems and methods.

The registration subsystem 120D may be configured to register, align, and/or otherwise reconcile various types of data associated with the built environment. The registration subsystem 120D may be configured to register or otherwise align various types of imaging data comprising the scan data among each other, and/or with the build data. The registration subsystem 120D may perform the registration via one or more image processing techniques (e.g., via algorithms, models, etc.) to compute and/or align correspondences between different imaging modalities based upon one or more transformations which align features (e.g., elements and corresponding physical components) to a common coordinate system, often by finding or intensities. For example, the scan data may include different scan datasets each captured at a different pose using a different imaging modality. The registration subsystem 120D may perform a fusion of the scan datasets by aligning each scan dataset to common coordinate system. The registration subsystem 120D may perform data preprocessing that includes registering scan datasets, cleaning and/or filtering the scan data (e.g., remove outliers and/or imaging sensor noise), managing occlusions (e.g., where building elements are partially or entirely obscured), and/or other suitable data preprocessing. The data preprocessing may allow the system 105 to more accurately match the imaging data associated with physical components with the corresponding elements build data.

The analysis subsystem 120E may be configured to analyze the graph structure of the built environment to determine the status of built environment, such as the status of physical components of the physical built environment respective to the corresponding digital elements of the digitally-modeled built environment. The analysis subsystem 120E may cause the TGNN model 118C to analyze the graph and make inferences, predictions, and/or otherwise determinations about the status of one or building elements, such as whether the wall is correctly positioned within a room, if the window is present or missing, if a door is built within allowed tolerances, and/or if a built task is running on, behind, or ahead of schedule. To this end, the analysis subsystem 120E may classify one or more building elements into categories, such as verified (built as-designed within allowed tolerances), deviated (built outside of allowed tolerances), missing (not built or not detected), no data (insufficient information for classification), and/or any other suitable classification. This classification may provide a detailed understanding of the progress and/or status of the built environment to highlight portion of the built environment that need attention (e.g., are running behind) and/or are built according to specification. The analysis subsystem 120E may apply a set of predefined rules and/or standards when analyzing the built project to ensure it is aligned with one or more requirements. The predefined rules and/or standards may indicate and/or be associated with construction tolerances, safety standards, regulatory compliance, and/or the like, to determine whether the current state of construction of the built environment meets required levels of quality. By applying the predefined rules and/or standards, the analysis subsystem 120E can provide a detailed and objective evaluation of the quality and/or state of the built environment, enabling the one or more users to make informed decisions about necessary adjustments and corrections to maintain project standards.

The output subsystem 120F may be configured to generate built status data providing information associated with the status of the built environment, for example based upon classifying information provided via the graph. The output subsystem 120F can provide a clear and concise understanding of the state of construction of the built environment at one or more points in time, indicating any issues that need addressing. The built status data may include one or more reports, such as a report that textually summarizes the overall status of the construction of the built environment, outlines and/or otherwise identifies issues, and/or provides suggestions for corrective actions. The report can provide a thorough analysis of the project's progress and quality, serving as a valuable resource for project documentation and decision-making. The built status data may include one or more multimedia representations (e.g., images, video, charts, tables, graphs, audio, augmented reality, virtual reality) indicating the built environment status, such as status at a per-element level, causing a recipient of the built status data to sensorily identify areas of concern, such as deviations from the original design or missing elements. For example the built status data may include a video of the built environment with augmented information (visual and auditory overlays) indicating the status of elements of the built environment.

The output subsystem 120F may be configured to learn (e.g., based upon user feedback) from previous built environment status determinations and retrain the TGNN model 118C, improving the ability of the TGNN model 118C to analyze elements indicated as partially observed and/or no data. The output subsystem 120F may be configured to refine heuristic-based methods, reducing reliance on rigid, predefined rules and enabling the system 105 to become more adaptive, robust, and scalable over time. The heuristic-based methods refer to the simplified rules and guidelines used to assess build quality when associated data (e.g., scan data) is incomplete or noisy. The ability to continuously learn and improve can allow the system 105 to consider dynamic and evolving requirements of construction quality assessments.

The memory 104 may store build status application 130. The build status application 130 may cause the system 105 or other component/device executing the build status application 130 (e.g., the imaging device 140, the computing device 160) to perform one or more functions associated with determining the status of a built environment (e.g., in real-time), such as generating, analyzing, storing, and/or transmitting data (e.g., build, scan, scheduling, and/or build status data), generating a graph, communicating with other components/devices (e.g., the imaging device 140, the computing device 160), and/or other suitable functions. Accordingly, the build status application 130 may interact with components and/or devices of the computing environment 100, such the network 110, the model 118, the subsystems 120, the imaging device 140, and/or the computing device 160.

The network 110 may generally enable bidirectional communication between devices and/or components of the computing environment 100, such as the system 105, the imaging device 140, the database 135, and/or the computing device 160. The network 110 may be, and/or include, one or more wired communication networks and/or a wireless communication network. The wired communication network may include one or more Ethernet connections, Fiber Optics, Power Line Communications (PLCs), Serial Communications, Coaxial Cables, Quantum Communication, Advanced Fiber Optics, Hybrid Networks, and the like. The wireless communication network may include one or more of wireless fidelity (Wi-Fi), cellular networks (e.g., fourth generation (4G), fifth generation (5G), sixth generation (6G), Bluetooth®, ZigBee®, long-range wide area network (LoRaWAN), satellite communication, radio frequency identification (RFID), internet-of-things (IoT) networks, mesh networks, non-terrestrial networks (NTNs), near field communication (NFC), and the like. The network 110 may include any suitable network or networks, including a local area network (LAN), wide area network (WAN), Internet, and/or combination thereof. In one aspect, the network 110 may include a cellular base station, such as cellular tower(s), communicating to the one or more components of the computing environment 100 via wired/wireless communications based upon any one or more of various mobile phone standards, including Global System for Mobile Communications® (GSM), Code Division Multiple Access® (CDMA), Universal Mobile Telecommunications System® (UMTS), Long Term Evolution® (LTE), Ultra-wideband® (UWB), and/or the like. Additionally, or alternatively, the network 110 may include one or more routers, wireless switches, or other such wireless connection points communicating to the components of the computing environment 100 via wireless communications based upon any one or more of various wireless standards, including by non-limiting example, IEEE® 802.11 a/ac/ax/b/c/g/n (Wi-Fi), Bluetooth®, and/or the like.

The imaging device 140 may be configured to obtain, generate, store and/or other process scan data. In at least some implementations, the imaging device 140 may be, or include, one or more off a quadruped, a wheeled robot, a biped, a drone, an unmanned arial vehicle (UAV), an unmanned terrestrial vehicle (UTV), and/or other suitable type of robot. The imaging device 140 may include a processor 142 (e.g., the processor 102) a memory 104 (e.g., the memory 104), a network interface 146 (e.g., the network interface 106), a user interface 148 (e.g., the user interface 108). The memory 144 may be one or more of the subsystems 120 (e.g., the registration subsystem 120D), and/or the build status application 130 (e.g., to cause the imaging device 140 to perform functions associated with the scan data). The build status application 130 of the imaging device 140 may include the same, or similar, functionality as the build status application 130 of the system 105.

The imaging device 140 may include one or more sensors 150. The one or more sensors 150 may be configured capture sensor data, such as data include in, and/or associated with, the scan data. The scan data may indicate one or more of when (e.g., timestamp) and/or where (e.g., GPS coordinates) the scan data is captured, the type of imaging device capturing the scan data (e.g., characteristics of the sensor 150 capturing the scan data), the pose of the imaging device when capturing the scan data, the environmental conditions when capturing the scan data (e.g., lighting, weather, etc.), and/or any other suitable information. The sensors 150 may include, but are not restricted to, one or more imaging sensors (e.g., camera, complementary metal-oxide-semiconductor (CMOS), light detection and ranging (LIDAR), radio detection and ranging (RADAR), infrared (IR)), navigation sensors (e.g., global position system (GPS), inertial measurement unit (IMU)), environmental sensors (e.g., humidity, temperature, wind, ultra-violet (UV)), and/or any other suitable sensor. In one example, the one or more sensors 150 may include a camera configured to capture scan data including images and/or video of the built environment, and a LIDAR sensor configured to capture scan data including a point cloud of the built environment. The scan data may include the images and/or video generated by the camera and the point cloud generated by the LIDAR sensor. Each type of sensor data may provide different information about the built environment, such as the shape, size, visibility (e.g., due to obstacles or other elements) of elements of the built environment, the weather conditions while capturing the scan data weather, etc. The imaging device 140 may be configured to operate (e.g., navigate, perform scans of the built environment) autonomously without intervention (e.g., input, feedback, control, etc., from another device and/or user), semiautonomously with at least some intervention, and/or anything therebetween. For example, in implementations where the imaging device 140 is a UAV configured to operate autonomously, the UAV may execute the build status application 130 causing the UAV fly though the built environment while capturing scan data and transmit the scan data to the system 105 via the network 110.

The computing environment 100 may include, and/or have access to (e.g., via the network 110) the database 135. The database 135 may be a relational database, such as Oracle®, DB2®, MySQL®, a NoSQL® based database, such as MongoDB®, or another suitable database. The database 135 may store data and/or datasets include one or more types of data, records, files, etc., however, the terms “data” and “dataset” may be used interchangeably herein. In at least some implementations, the database 135 may store and/or manage data associated with determining the status of a built environment, such as storing build, scan, schedule, and/or build status data, graphs, trained models (e.g., the model 118), model training data, and/or other suitable data. The database 135 may enable efficient data retrieval and/or analysis to support decision-making processes associated with determining the status of a built environment. For example, the database 135 may be configured to store reports indicating and/or otherwise associated with the status of the built environment.

The computing environment 100 may include at least one computing device 160. The computing device may be associated with a user providing, analyzing, receiving, and/or otherwise processing information associated with the status of the built environment. For example, a user of the computing device 160 may be a site manager who is monitoring the progress of construction of the built environment. The computing device 160 may include one or more user devices, mobile devices, smartphones, Personal Digital Assistants (PDAs), tablet computers, phablet computers, wearable computing devices, virtual reality (VR) devices, augmented reality (AR) devices, laptops, desktops, display interface panels, control panels, human machine interface panels, liquid crystal display (LCD) screens, light-emitting diode (LED) screens, and the like. The computing device 160 may include a processor 162 (e.g., the processor 102, 142) a memory 164 (e.g., the memory 104, 144), a network interface 166 (e.g., the network interface 106, 146), a user interface 168 (e.g., the user interface 108, 148).

The memory 164 may include the build status application 130 including the same, or similar, functionality as the build status application 130 of the system 105 and/or imaging device 140. In at least some implementations, the build status application 130 may allow a user of the computing device 160 to receiving real-time information associated with the status of the built environment, such as receiving reports of the progress of construction of the built environment over time form the system 105 via the network 110. In another example, the build status application 130 may allow the user to control the imaging device 140, for example causing the imaging device 140 to capture scan data of the built environment.

The computing environment 100 may include additional, fewer, and/or alternate components, and may be configured to perform additional, fewer, or alternate actions, including components/actions described herein. Although the computing environment 100 is shown in FIG. 1 as including one instance of various components such as the system 105, the database 135, the imaging device 140, and the computing device 160, various aspects include the computing environment 100 implementing any suitable number of any of the components shown in FIG. 1 and/or omitting any suitable ones of the components shown in FIG. 1. For example, the computing environment 100 may include a plurality of imaging devices 140, each configured to capture scan data of different portions of the built environment. Moreover, data described as being stored in the database 135 may be stored in the memory 104 of the system 105 and/or the memory 144 of the imaging device 140, and therefore the database 135 may be omitted. Moreover, various aspects include the computing environment 100 including any suitable additional component(s) not shown in FIG. 1, such as but not limited to the exemplary components described above. Furthermore, it should be appreciated that additional and/or alternative connections between components shown in FIG. 1 may be implemented. As just one example, system 105 and the database 135 may be connected via a direct communication link (not shown in FIG. 1) instead of, or in addition to, via the network 110.

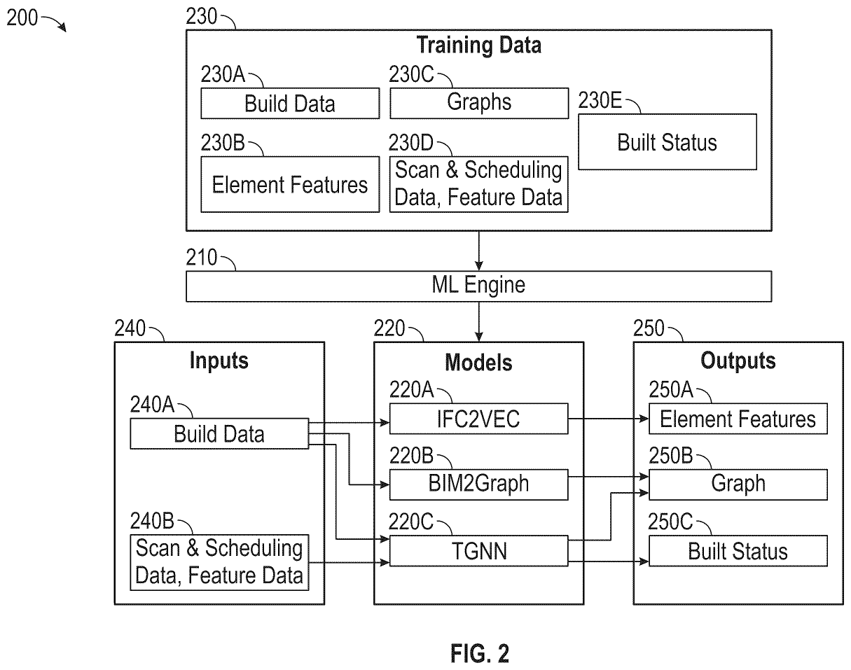

FIG. 2 is a block diagram 200 depicting an example training process of a machine learning model (e.g., the model 118), in one implementation of the instant application. Generally, a machine learning (ML) engine 210 (e.g., the ML module 114) trains a model 220 using training data 230. The ML engine 210 may train the ML model 220 via regression, k-nearest neighbor, support vector regression, and/or random forest algorithms and/or models, although any type of applicable ML algorithm and/or model may be used. Model training may be performed via one or more of supervised learning, unsupervised learning, semi-supervised learning, and/or reinforcement learning. Once trained, the ML model 220 may perform operations on one or more data inputs 240 to produce a desired data output 250.

The model 220 may include an IFC2VEC model 220A configured to receive build data 230A as an input 240, and in response generate an output 250 element features 250A (e.g., BIM-based features) indicated by the build data. The element features 250A may be based upon semantics of the hierarchical relationships of the elements indicated in the Industry Foundation Classes (IFC) schema of the build data. In at least some implementations, the IFC2VEC model 220A may generate one or more vectors that encode the element features 250A, such as vectors encoding the element's properties and its context within the building as indicated by the build data. For example, the IFC schema may indicate for a door its dimensions (e.g., length, width, height), composition material (e.g., steel, wood), location (e.g., a wall within the built environment), its hierarchical relationship to other elements (e.g., the wall in which the door is located and opening in the wall filled by the door as parental relationships and a hole in the door to be filled by a door handle and the door handle filling the hole as child relationships), and/or any other suitable relationship. The IFC2VEC model 220A may be trained by the ML engine 210 using training data 230 that includes historical build data 230A and historical element features 230B indicated by the historical build data 230A. The ML engine 210 may be configured to process the training data 230 to learn associations and relationships in the training data 230, e.g., relationships indicating which historical element features 230B are indicated by the IFC schema of the historical build data 230A. For example, the IFC2VEC model 220A may learn syntax associated with the IFC schema to understand that “IFCDoor” is associated with a door element. The ML engine 210 may train the IFC2VEC model 220A based upon the learned associations and relationships causing the trained IFC2VEC model 220A to be able to successfully generate accurate element features 250A when receiving new build data 240A it has not previously received as the input 240.

The model 220 may include an BIM2GRAPH model 220B configured to receive the build data 240A as the input 240. In response to receiving the build data 240A, the BIM2GRAPH model 220B may generate as an output 250 a graph 250B representing the built environment. The graph 250B may be, and/or include, a dynamic four-dimensional (4D) spatio-temporal graph having nodes including element node corresponding to elements of the BIM data. The graph 250B may include edges, each corresponding to a relationship between the two nodes connected by the edge, such as topical and spatial relationships. The BIM2GRAPH model 220B may be trained by the ML engine 210 using training data 230 that includes historical build data 230A and historical graphs 230C generated based upon the historical build data 230A. The ML engine 210 may be configured to process the training data 230 to learn associations and relationships in the training data 230, e.g., relationships indicating the IFC schema of the historical build data 230A that indicates nodes and edges of the associated historical graphs 230C. For example, the BIM2GRAPH model 220B may learn syntax associated with the IFC schema to understand that “IFCWindow” is associated with node corresponding to a door window. The ML engine 210 may train the BIM2GRAPH model 220B based upon the learned associations and relationships causing the trained BIM2GRAPH model 220B to be able to successfully generate the graph 250B representing a built environment based upon receiving build data 240A it has not previously received as the input 240.

The model 220 may include a temporal graphing neural network (TGNN) model 220C trained to generate as an output 250 the graph 250B based upon receiving the build data 240A and scan, scheduling, and feature (e.g., BIM-based, scan-based, scheduling-based and graph-based features) data 240B as the input. The graph 250B may be, and/or include, a dynamic four-dimensional (4D) spatio-temporal graph having nodes including element node corresponding to elements of the BIM data, task nodes corresponding to built tasks for constructing the built environment, and scan nodes corresponding to scans of the built environment. The graph 250B may include edges, each corresponding to a relationship between the two nodes connected by the edge, such as topical, spatial, and/or a temporal relationships. The TGNN model 220C may be trained by the ML engine 210 using training data 230 that includes historical build data 230A, historical scan & scheduling data, feature data 230D, and historical graphs 230C generated based upon the historical build data 230A. The ML engine 210 may be configured to process the training data 230 to learn associations and relationships in the training data 230, e.g., relationships indicating the IFC schema, scan data, scheduling data and feature data of the historical build data 230A and historical scan, scheduling, and feature data 230D that indicates nodes, node features, edges, and edge attributes of the associated historical graphs 230C. The ML engine 210 may train the TGNN model 220C based upon the learned associations and relationships causing the trained TGNN model 220C to be able to successfully generate the graph 250B representing a built environment based upon receiving the build data 240A and scan, scheduling, and feature (e.g., BIM-based, scan-based, scheduling-based and graph-based features) data 240B as the input.

The TGNN model 220C may be trained to generate as an output 250 built status data 250C (e.g., status reports) indicating the status of the built environment based upon analyzing the graph 240C (e.g., augmented with BIM-based features, graph-based features, scan-based features, and scheduling-based features). The TGNN model 118C may include a classifier configured to generate element classifications (e.g., verified, deviated, missing, and no data) indicating or otherwise associated with a built status based upon information indicted in the augmented graph.

The TGNN model 220C may be trained by the ML engine 210 using training data 230 that includes the historical augmented graphs of the historical graphs 230C data and associated historical build status data 230E. The ML engine 210 may be configured to process the training data 230 to learn associations and relationships in the training data 230, e.g., relationships indicating the built status indicated in the historical build status data 230E is behind schedule when a threshold number of elements are indicated as deviated and/or missing in the graph 240C. The ML engine 210 may train the TGNN model 220C based upon the learned associations and relationships causing the trained TGNN model 220C to be able to successfully generate the built status data 250C associated with the built environment based upon analyzing the associated graph 240C it has not previously analyzed.

The ML engine 210 may retrain one or more of the models 220 using updated training data 230, for example to improve operation of the model 220, cause the model 220 to have additional capabilities, etc. For example, the IFC schema may be revised to include new syntax, and the IFC2VEC model 220A may be retrained using updated build data 240A that includes the new IFC schema syntax so that when the retraining model received new build data 240A including the new syntax, the IFC2VEC model 220A is able to successfully generate associated element features 250A whereas before the IFC2VEC model 220A is retrained it would not be able to generate accurate element features 250A.

It should be understood that functionality attributed to a single model 220 may be performed by two or more models, and similar functionality associated with multiple models may be performed by fewer models. For example, the BIM2GRAPH model 220B may include a first model trained to generate the graph 250B and a second model trained to generate the built status data 250C. Moreover, while model training and execution may be described as being performed on the same device (e.g., the system 105), it should be understood that one device may train the model (e.g., the system 105) and another device may execute the trained model (e.g., the computing device 160), such that the model 220 may not be trained and executed by the same device.

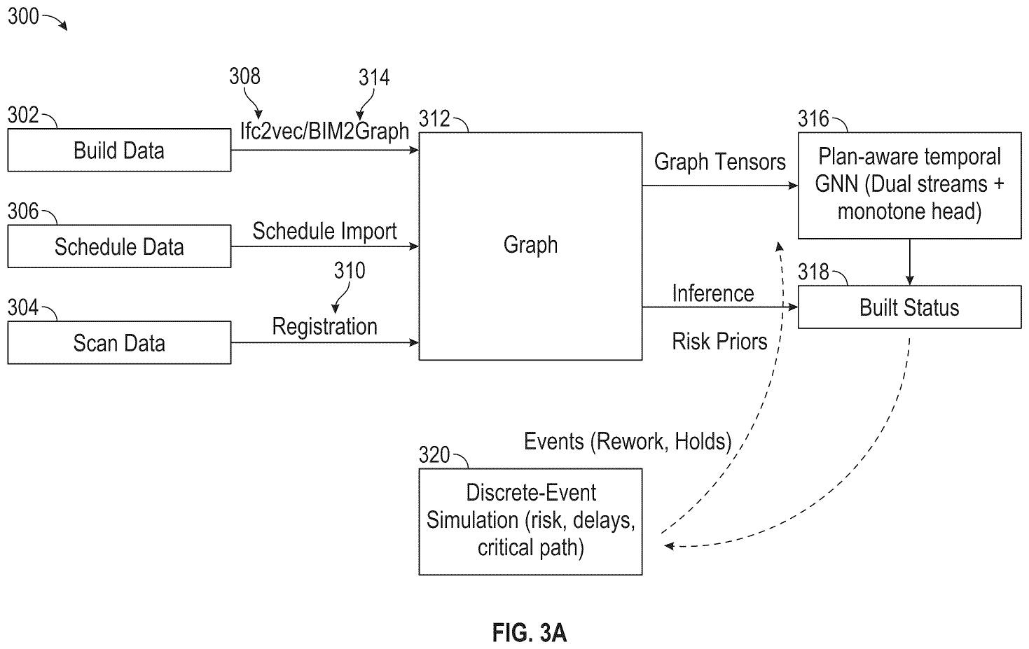

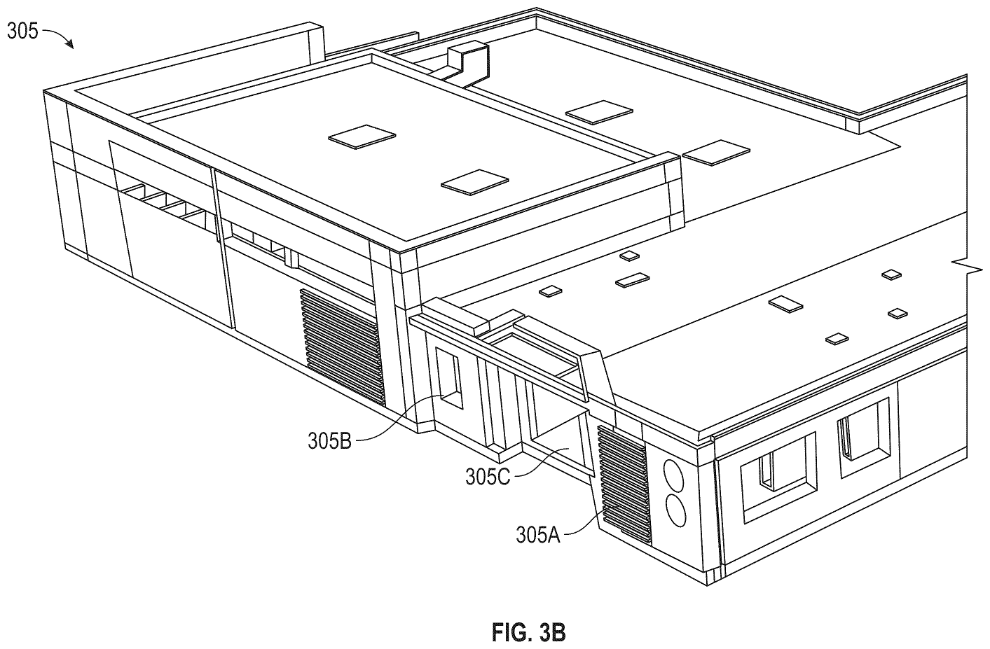

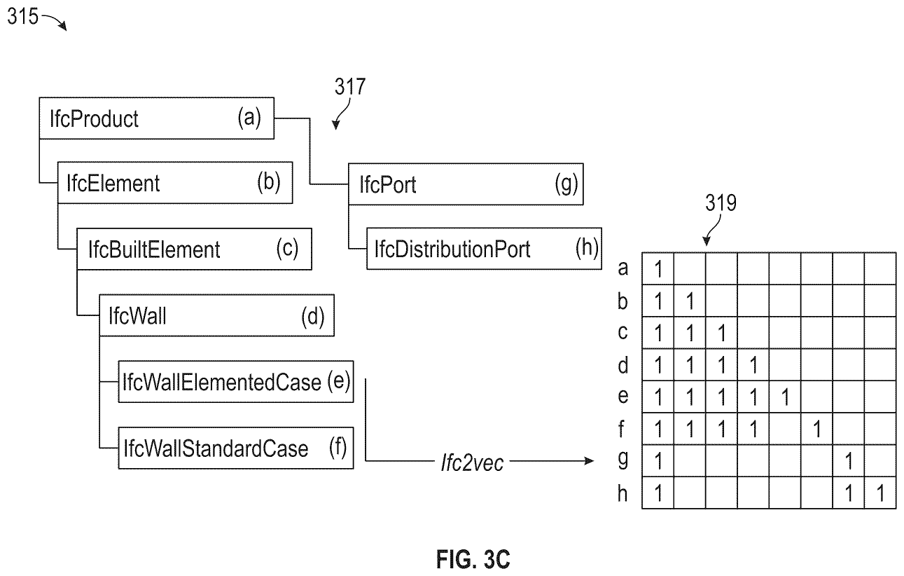

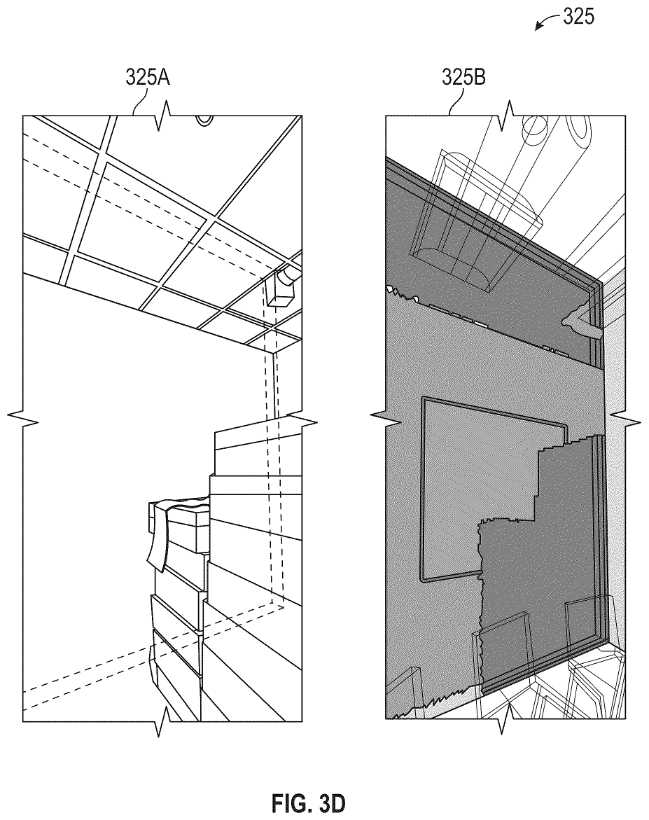

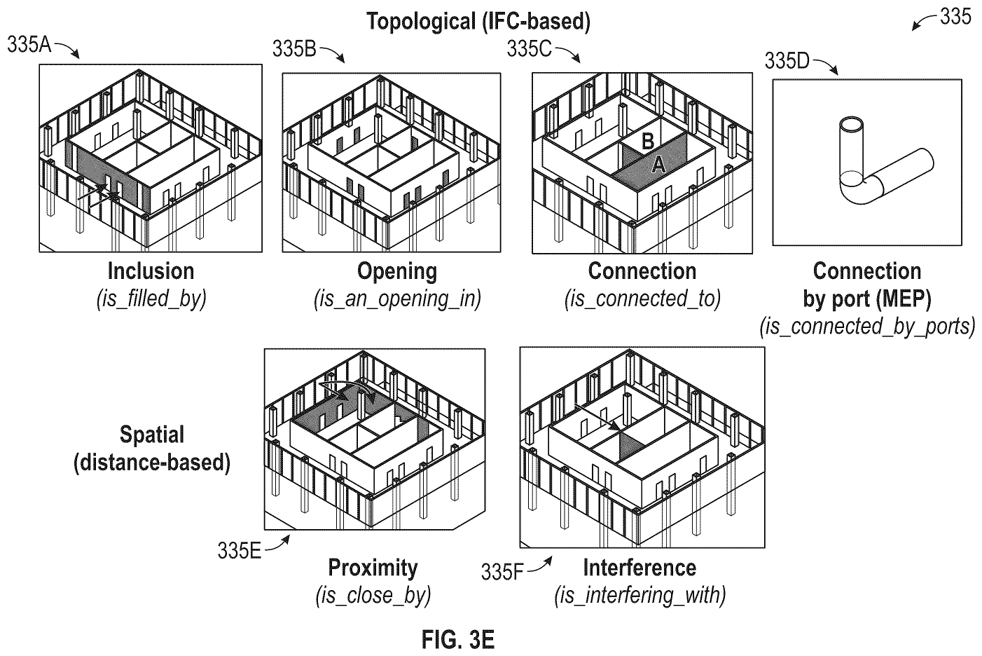

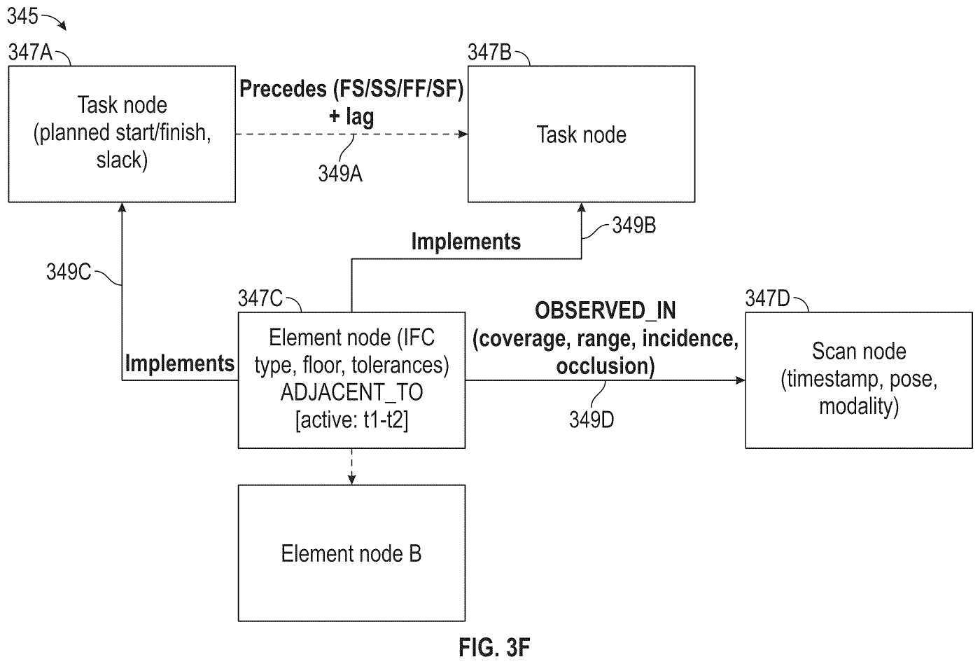

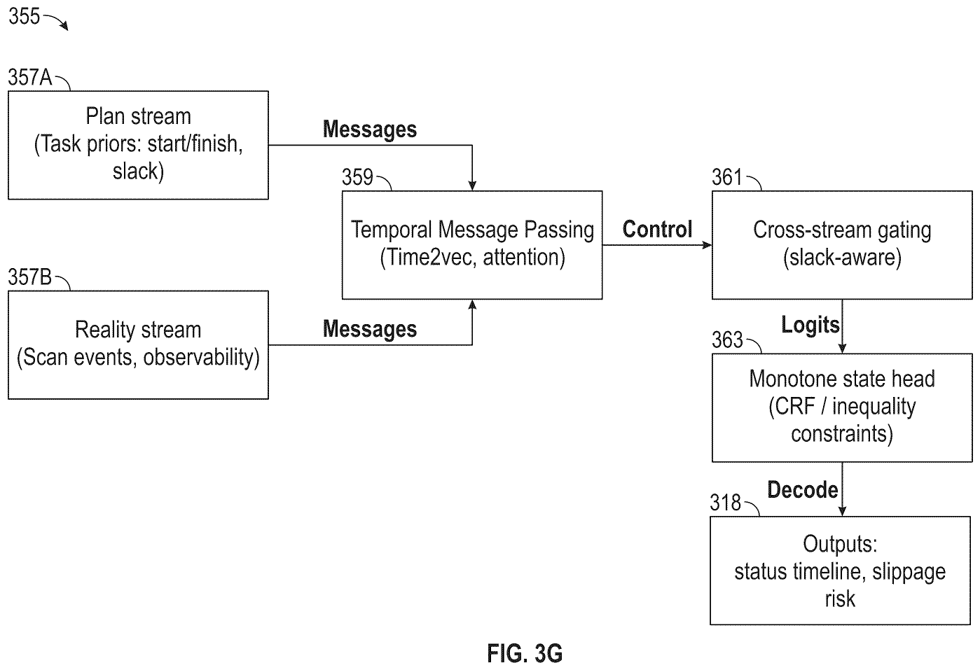

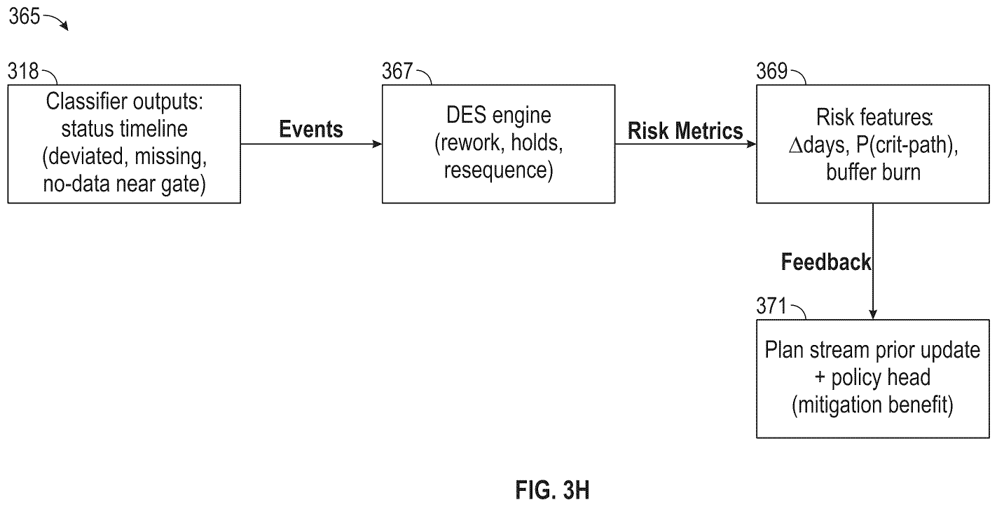

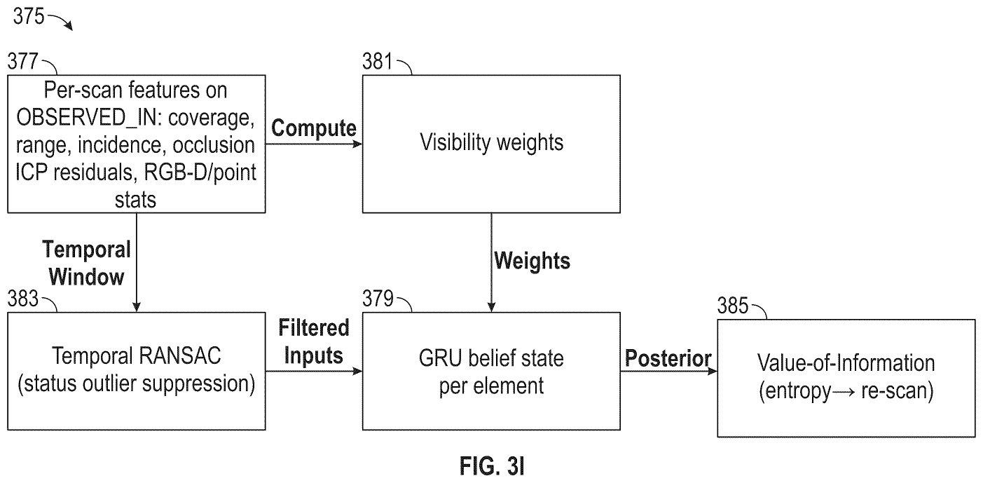

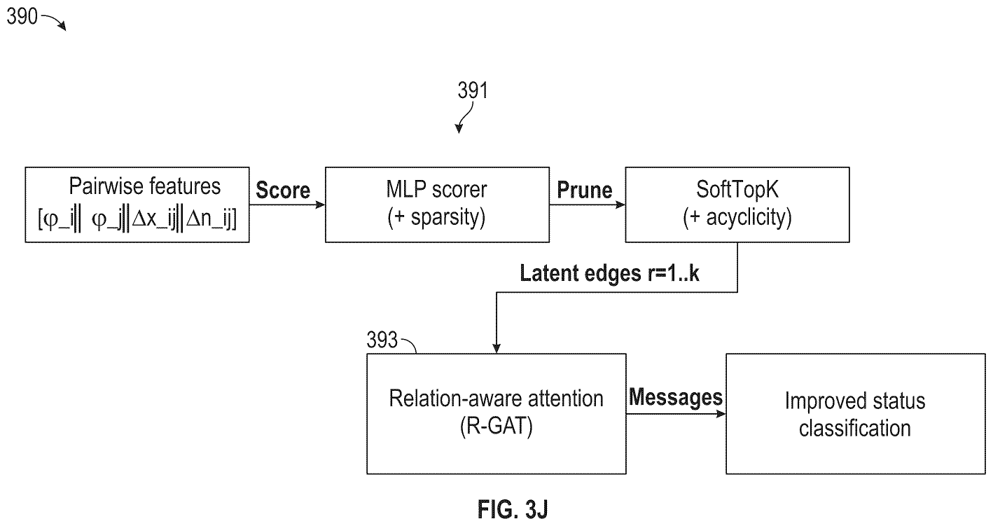

FIG. 3A is a block diagram of an exemplary workflow 300 for determining the status of a built environment, in one implementation of the instant application. One or more steps, functions, processes, etc., of the workflow 300 may be performed via the computing environment 100 (e.g., the system 105, the imaging device 140, the computing device 160).

The workflow 300 may include obtaining (e.g., via the data-obtaining subsystem 120A) build data 302, scan data 304, and scheduling data 306. The build data 302 may include a building information model (BIM) of the built environment, for example a model depicting all of elements of the built environment and their associated specifications (e.g., shape, size, material, tolerance, location, etc.). The elements of the virtual built environment modeled by the BIM may correspond to physical components of the real-world built environment. The build data may include an Industry Foundation Classes (IFC) schema associated with the BIM. The IFC schema may indicate hierarchical relationships between the plurality of elements, wherein each class of the schema has associations with others. As an example, the IFC schema can organize the following example building elements into a hierarchy, with relationships like IfcRelAggregates linking IfcBuilding to its IfcBuildingStorey entities, and IfcRelContainedInSpatialStructure then linking the story to the objects within it. IfcRelAggregates describes a hierarchical structure, for example, connecting an entire building (IfcBuilding) to its constituent levels or stories (IfcBuildingStorcy). IfcRelContainedInSpatialStructure demonstrates how spatial entities are contained within others, such as a wall IfcWall being contained within a specific level IfcBuildingStorey. IfcRelConnectsPathElements show relationships between contiguous entities, like two walls (IfcWallStandardCase) that are connected to each other.

FIG. 3B depicts an example BIM 305 of a built environment, in one implementation of the instant application. The BIM 305 includes first element 305A modeling a physical wall of the built environment, a second element 305B modeling a physical hole in the wall for insertion of a window, and a third element 305C modeling a physical hole in the wall of the built environment for insertion of a door. The IFC schema associated with the BIM 305 may indicate hierarchical relationships between the wall elements and the hole elements for the window and the door, as just described above.

The IFC2VEC model 308 (e.g., the IFC2VEC model 118A, 220A) may receive the build data 302 and convert the IFC hierarchical schema (e.g., IFC2X3) into a vectorized representation (e.g., as vectorized data) of BIM-based features. The BIM-based features may indicate features indicating hierarchical relationships of the plurality of elements based upon semantics of the IFC schema of the build data, such as the type of element type and floor, and/or any other suitable information of the build data 302 (e.g., an IFC type, a geometry hash, a tolerance). The IFC2VEC model 308 may convert the IFC schema into a look-up dictionary, encoding element types considering their semantic relationships in learning-based or data-mining tasks. The hierarchical inheritance relationships may be extracted between the IFC classes and represented as a tree. In at least some implementations, this may include implementing ifcOWL aWeb Ontology Language (OWL) representation of the IFC schema.

FIG. 3C depicts a block diagram 315 of an example tree 317 generated by the IFC2VEC model 308, in one implementation of the instant application. The tree 317 may include a root, IfcProduct, as the highest level in the IFC schema of importance for purposes of generating built status. The child branches of the tree may inherit classes from the parent branches connected at higher levels of the tree 317. By mapping a portion of the IFC schema to the tree 317, the IFC classes can be represented as binary vectors 319 indicating the path from the root to its node in the tree. The sub-classes IfcWall include siblings IfcWallElementedCase and IfcWallStandardCase, which have a closer vector embedding in IFC2VEC than dissimilar classes such as IfcPort and IfcDistributionPort of the tree 317.

The workflow 300 may include performing a registration 310 of the scan data 304 with the build data 304. The registration 310 may determine element-wise correspondences between elements modeled in the BIM of the build data 302 and their corresponding physical components indicated in the scan data 304. Accordingly, the registration 310 may be based upon the elements indicated in the build data 302 and the physical components and pose information indicated in the scan data 304.

On cluttered construction sites, the captured scan data 304 may suffer from data incompleteness due to occlusions of physical elements (e.g., from obstacles, other elements), sensor noise, weather conditions (e.g., illumination) during scanning, and material properties of the physical element (e.g., reflective, transparency), thereby resulting in the partial observability of the physical components of the built environment. Considering the relationships (e.g., spatial, topological, and/or temporal) between physical elements and their virtual element counterparts may enhance quality control assessments of the built environment and/or compensate for sources of noise or other data incompleteness.

As an example, FIG. 3D depicts a set of images 325 associated with a built environment, in one implementation of the instant application. More specifically, a first image 325A depicts a built environment and a second image 325B depicts the corresponding scan data. The set of images 325 depict a wall occluded by a ceiling and boxes. The wall may be challenging for heuristics to classify in the second image 325B due to the occlusion. Existing ML-based solutions often assume that the data corresponding to the individual elements is complete and independent and identically distributed. To handle incomplete data in element-wise change detection, a hierarchical deep variational autoencoder point cloud completion may be implemented. The disclosed techniques may consider a project-level context as well as an elements' associations to address the partial observability problem to make more reliable ML-based quality assessments at the individual element level.

In at least some implementations, the scan data 304 captured by the imaging device 140 (e.g., cameras or LIDAR) may be transformed into registered three-dimensional point cloud, for example using three-dimensional reconstruction methods and iterative closest point (ICP) algorithms. The scan data 304, including the point cloud, may undergo preprocessing, such a performing registration of different scan dataset (e.g., captured at different times, captured at different poses, captured by different imaging devices 140 and/or sensors 150) of the scan data 304 into a single global coordinate frame. The system 105 may perform (e.g., via the registration subsystem 120D) preprocessing of the point cloud or otherwise scan data 304 to remove outliers, reduce noise, down-sample and/or compress data, and/or perform data imputations. The preprocessed scan data such may be compared with the BIM for inference. Comparisons between the BIM and preprocessed scan data can be performed based on heuristics and/or using ML techniques. While heuristic approaches may be simple to perform (e.g., require no labeled data), they may lose their effectiveness in the presence of noise, clutter, and scan drifts. To be more resilient to noise and clutter, a heuristic metric quality control approach may be performed that corrects for scan registration drifts using local transformations, identifies construction errors for each element, and classifies them based on fixed thresholds. However, quality assessments based on heuristics can be limited in terms of adaptability, scalability, and accuracy, as accurately capturing construction complexity based on predefined thresholds and conditions is an impracticable task.

The workflow 300 may include generating the scan-based features (e.g., as vectorized data) from the scan data 304, such as the registered scan data. The scan-based features may include a timestamp, an imaging device pose, a scan modality, a coverage mask, and/or any other suitable feature of the scan data 301. In at least some implementations, the scan-based features may be included in the scan data 304 (e.g., as metadata, labels, etc.), such that generating the scan-based features includes extracting the scan-based features from the scan data 304. Scan-based features may include BaselineML and PointNet features. BaselineML features may be generated by a BaselineML model and may include a set of engineered features that quantify the degree to which the BIM elements match the scans. The PointNet features may be generated by a PointNet model and may include features such as scanned fraction and relative alignment error. PointNet features may be extracted from the latent representation of the last two layers of a pre-trained Pointnet model. Scan-based features may include BaselineML and PointNet features. BaselineML features may be generated by a BaselineML model and may include a set of hand-engineered features that quantify the degree to which the BIM elements match the scans. The PointNet features may be generated by a PointNet model and may include features such as scanned fraction and relative alignment error. PointNet features may be extracted from the latent representation of the last two layers of a pre-trained Pointnet model.

The workflow 300 may include generating scheduling-based features (e.g., as vectorized data) from the scheduling data 306. For example, the scheduling data 306 may indicate the amount of time a built task can be delayed without impacting its immediate successor built task which may be referred to as free slack, or the overall project completion which may be referred to as referred to as total slack. Slack may be applied as a temporal feature to task nodes and may be used to define grace windows in loss functions and to govern gating of plan-stream messages, as further described below. The scheduling-based features may indicate characteristics associated with performing each of the built tasks indicated the scheduling data, such as a work breakdown structure identifier, an assigned work crew, a productivity prior, a calendar, a built task start time, a built task completion time, a built task slack, a built task precedence, and/or any other suitable feature of the scheduling data 306. In at least some implementations, the scheduling-based features may be included in the scheduling data 306 (e.g., as metadata, labels, etc.), such that generating the scheduling-based features includes extracting the scheduling-based features from the scheduling data 306.

The 300 may include providing the build data and the BIM-based features generated therefrom, the scan data and the associated scan-based features generated therefrom, and the scheduling data and the scheduling-based features generated therefrom as an input to a TGNN (e.g., the TGNN model 118C, 220C). In response to receiving the input, the TGNN may generate a graph 312, such as a dynamic four-dimensional spatio-temporal graph. The graph 312 may include nodes connected by edges. The nodes may include element nodes corresponding to elements of the BIM (e.g., indicated by the build data 302), task nodes corresponding to built tasks (e.g., indicted by the scheduling data 306), and scan nodes corresponding a scan (e.g., indicted by the scan data 304). Two nodes may be connected by edges representing relationships if they are topologically, spatially, or temporally related.

In at least some implementations, the BIM2GRAPH model 314 (e.g., the BIM2GRAPH model 118B, 220B) may generate at least a portion of the graph 312 based upon the build data 302. In some such implementations, in response to receiving the build data 302, the BIM2GRAPH model 314 may generate at least a portion of the graph 312 indicated by the BIM, such as the element nodes and edges connecting elements. The BIM may indicate topological relationships of elements based upon the hierarchical relationships indicated by the IFC schema and/or spatial relationships of elements based upon respective distances (e.g., the distance between axis-aligned bounding boxes) between the elements as modeled by the BIM. Accordingly, the BIM2GRAPH model 314 may generate at least a portion of the graph 312 associated with elements and edges connected elements as indicated by their topological and/or spatial relationships.

FIG. 3E depicts an example set of images 335 of example topical and spatial relationships of BIM elements, in one implementation of the instant application. The topological relationships may include inclusion depicted by image 335A, an opening depicted by image 335B, a connection depicted by depicted by image 335C, or a connection by port depicted by image 335D, although other topical relationships may be considered by the disclosed techniques. An inclusion relationship may refer to the relationship between a container element (e.g., wall) and a filler element (e.g., door). For example, a wall instance of the IfcWall class (e.g., IfcWallStandard) would be connected to an IfcOpeningElement through an IfcRelVoidsElement. A door in the same wall would be an instance of the IfcDoor class and would be connected to the same IfcOpeningElement through an IfcRelFillsElement. An opening relationship may describe the association between a void and its container, which may or may not be filled by a filler element. A connection relationship may be defined using IfcRelConnectsElements, and may describe the elements' connectivity with a connection geometry (such as a point, curve, or surface). For example, walls A and B in image 335C would be connected through a surface and not through any other element. A connection by port relationship captures the connection between mechanical, electrical, and/or plumbing (MEP) elements (e.g., IfcPort) at their point of connection through the objectified relationship IfcRelConnectsPorts.

The spatial relationships may include proximity as depicted by image 335E and interference as depicted by image 335F, although other spatial relationships may be considered by the disclosed techniques. The spatial relationships may capture the connections between nearby elements. The build status application may generate (e.g., via the BIM2GRAPH model 314) a distance matrix based on the minimum distance between the objects' axis-aligned bounding boxes (AABB), allowing for efficient three-dimensional distance calculations and manipulation. Determining the AABB may include wrapping objects in non-rotated rectangular boxes whose faces are axis-aligned. The distance (d) between two AABBs, A and B, represented by their bottom-left (min) and top-right (max) corners' coordinates in 3D can be found using the equation

$$d = \sqrt{{\vert \vec{u} \vert}^{2} + {\vert \vec{v} \vert}^{2}} \vec{u} , \vec{v} ∈ {R}^{3}$$

The spatial relationships may be established based on three thresholds: the proximity thresholds dcₘᵢₙ and dcₘₐₓ; and the interference threshold dint of the following equation:

$$spatial ( d ) = \{ \begin{matrix}proximity , & {d}_{cmin} \leq d \leq {d}_{cmax} \\ interference , & d \leq min ( {d}_{int} , {d}_{cmin} ) \\ none , & otherwise\end{matrix}$$

Generating the graph 312 may include applying one or more features to a node, and one or more attributes to an edge. Accordingly, the features applied to an element node may indicate features of the corresponding element, the features applied to a task node may indicate features of the corresponding built task, and features applied to a scan node may indicate features of the corresponding scan. For example, an IFC type, a geometry hash, a discipline, a tolerance, a planned start time, a planned finish time, or slack may be features applied to an element node. A work breakdown structure identifier, an assigned work crew, a productivity prior, a calendar, a built task start time, a built task completion time, a built task slack, or a built task precedence may be features applied to a task node. A timestamp, an imaging device pose, a scan modality, or a coverage mask may be features applied to a scan node.

The node features may be based upon the BIM-based features (e.g., for element nodes), the scan-based features (e.g., for scan nodes), the schedule-based features (e.g., for task nodes). Moreover, the 300 may include generating graph-based features (e.g., as vectorized data) based up relationships of local neighborhoods of the plurality of nodes of the graph 312. Graph-based features indicate information about a node's local neighborhood, including node degree, eigenvector centrality, and clustering coefficient. Node degree may indicate the number of edges connected to the node. Eigenvector centrality may indicate the importance of the node in the graph. The clustering coefficient may indicate how the node's neighbors are connected to one another.

The attributes of the edges may indicate attributes of the relationship of elements connected by the edge, for example attributes learned from analyzing the graph 312. For example, the relationship between the two nodes corresponding to an edge may include a topological relationship based upon the hierarchical relationships indicated by the IFC schema, a spatial relationship based upon respective distances between the plurality of elements of the BIM, or a temporal relationship based upon sequential relationships indicated in the scheduling data. The attributes applied to the edges may include a precedes attribute applied to an edge connecting two task nodes and indicating a precedence of each of the two corresponding tasks, an observed attribute applied to an edge connecting the element node with the scan node and indicating observability of the corresponding element in the corresponding scan, and an implements attribute applied to an edge connecting the task node with the element node and indicating the corresponding built task includes the corresponding element.

FIG. 3F is a block diagram of a portion of an example graph 345, in one implementation of the instant application. The graph 345 includes task nodes 347A, 347B, element node 347C, task node 347D, and edges 349A, 349B, 349C, and 349D. The text within each of the nodes 347A-347D represents the associated features, and the text next to each of the edges 349A-349D represents the associated attributes.

In at least some implementations, the graph 322 may include a dynamic, four-dimensional spatio-temporal graph. One or more edges of the augmented graph 322 may appear and/or disappear over time (e.g., based upon receiving new and/or updates scan data 304 or scheduling data 306) and/or include event timestamps. In at least some implementations where the a dynamic, four-dimensional spatio-temporal graph, the Element nodes may include features such as IFC type (from ifc2vec), geometry hash, discipline, tolerances, planned start, planned finish, slack; the task nodes may include features such as WBS id, crew, productivity priors, calendars, planned start/finish, free/total slack; and the scan nodes may include features such as timestamp, scanner pose, scan modality (e.g., RGB-D, LiDAR), and coverage mask. Moreover, the edges may include timestamps and/or attributes such as a PRECEDES attribute of an edge connecting two task nodes may indicate schedule precedence (e.g., using finish (F) and start(s) attributes such as FS/SS/FF/SF) with lag; an OBSERVED IN attribute of an edge connecting and Element and scan node may indicate per-scan observability features (e.g., coverage %, distance, incidence, angle histogram, occlusion score, ICP fit residuals, RGB-D/point statistics; and an IMPLEMENTS edge connecting a task and task node may indicate a linking of scope to work packages. Further, spatial and topological edges (e.g., having attributes adjacent to, supports, contained in) may include time windows indicating when they are expected to be “active” according to the scheduling data.

The workflow 300 may include a TGNN model 316 (e.g., the TGNN model 118C, 220C) generating built status data 318 indicating the status of the built environment based upon analyzing the graph 312. In at least some implementations, generating the built status data 318 may include classifying the elements of the built environment with a classification selected from the group consisting of verified, deviated, missing, and no data, as previously described. The built status data 318 may include text, multimedia, documents, files, and/or any other suitable data. The built status data 318 may include one or more reports (e.g., summarizing construction of each physical structure corresponding to an element, identifying issues such as slippage risk, providing corrective actions, indicating built task timelines, etc.).

FIG. 3G is a block diagram of an example architecture 355 of the TGNN model 316, in one implementation of the instant application. The TGNN model 316 may include a continuous-time architecture (e.g., temporal Graph Attention (TGAT) and/or temporal Graph Network (TGN)) with dual message passing streams. The dual temporal message-passing pathways may operate over sequences of task (planned) and scan (actual) events, respectively. The dual streams may include a plan stream 357A that encodes precedence and planned windows from Task nodes, broadcasting timing and slack priors via IMPLEMENTS edges. The dual streams may include a reality stream 357B that encodes Scan evidence arriving out of order, to provide temporal message passing 359 using Time2Vec (Δt) encodings and temporal attention over OBSERVED IN events.

The TGNN model 316 may include cross-stream gating 361 that conditions messages on plan conformance, suppressing “early verification” messages before planned start unless negative slack is detected. Deviation sensitivity may increase near planned finish with low slack.

The TGNN model 316 may include a monotonic state machine head 363 wherein a final classifier enforces logical monotonicity with penalties (e.g., once verified, cannot transition back to missing unless a demolition task starts) and implemented via constrained CRF or inequality-penalized cross-entropy.

In at least some implementations, the workflow 300 may include performing discrete-event simulation (DES) 320 to identify one or more of a risk, a delay, or a critical path of the graph associated with the built environment. FIG. 3H is a block diagram of a workflow 365 for performing DES, in one implementation of the instant application. Performing the DES may include a DES-coupled risk engine 367 and a coupled learning-simulation loop. The coupled learning-simulation loop may include a loop from the TGNN model 316 to the DES engine 367 to convert element statuses to events including:

$$\begin{matrix}deviated \to Rework ( element , duration ∼ Log Normal ( μ r , σ r ) ) ; \\ missing past planned finish \to StartDelay ( task , Δ ) \\ no - data near gate \to InspectionHold ( task , τ )\end{matrix}$$

The coupled learning-simulation loop may include a loop from the DES engine 367 back to the TGNN model 316 to inject simulation outputs as risk features 369 on Task nodes, the risk features including expected days-lost, P (critical path hit), crew idling probability. The loop may feed the risk features 369 into the plan stream 371 of the TGNN model 316.

The DES 320 may provide decision support including: counterfactuals for a given deviation, simulate mitigation options (extra crew, resequencing); and a policy head to train to predict expected time-savings for each action, using DES outcomes as supervised targets. The metrics of the DES 320 may include schedule-level including a reduction in mean and 90th-percentile project delay when acting on model recommendations vs. baseline; and element-level including improvement in time-to-detect-critical-deviation and reduction in false holds that unnecessarily block work.

In at least some implementations, the workflow 300 may include performing multi-scan evidence fusion. Multi-scan evidence fusion may include combine, integrate, and/or otherwise process information from multiple scans (e.g., each generating scan data 304) of the built environment, or observations, of the same target or scene to achieve a more reliable outcome. This is especially useful in systems where sensors may be unreliable or produce conflicting data points. FIG. 3I is a block diagram of a workflow 375 for performing multi-scan evidence fusion, in one implementation of the instant application. The multi-scan evidence fusion may include receiving per-scan features on OBSERVED IN edges, 377, per-element GRU belief state 379 integrates irregular scan events with visibility-aware weights 381 on OBSERVED IN edges and temporal Random Sample Consensus (RANSAC) suppresses outlier statuses 383. An entropy-based Value-of-Information (Vol) 385 may suggest re-scans. For each element e, a belief state be (t) is maintained and updated by scan evidence using the equation:

$$b e ( t ) ← GRU ( be ( t - ) , [ coverage , ICP fit , ray angle hist , RGBD / point stats ] )$$

The multi-scan evidence fusion may include: an evidence fusion layer that may include a visibility model to weight evidence using visibility confidence computed from robot pose, range, grazing angle, and occlusion estimates; coordinate frame drift that may associate scans to elements through OBSERVED IN edges; and may include scan-to-scan factors and SE(3) correction nodes when alignment is uncertain.

Outlier suppression may include temporal RANSAC to Reject single-scan deviations not supported by neighboring scans within a +/−time window, and Bayesian re-observation policy to Output value-of-information score to request re-scan when posterior entropy of be remains high after conflicting observations.

In at least some implementations, TGNN model 316 may include a neural adjacency generator to discover latent relation types (e.g., co-installation, load-path) subject to sparsity and acyclicity constraints, consumed by a relation-aware attention GNN. FIG. 3J is a block diagram of a workflow 390 for performing differentiable relation discovery, in one implementation of the instant application. The neural adjacency generator 391 may learn K latent relation types as follows:

$$\begin{matrix}r ∈ \{ 1 … K \} : \\ A \hat{} ( r ) ij = SoftTopK ( MLPr ( [ ϕ i ‖ ϕ j ‖ Δx ij ‖ Δ nij ] ) )\end{matrix}$$

where r indexes latent relation types (e.g., load path, co-installation, shared trade), φ are node embeddings, and Δx, Δn encode spatial deltas. The GNN, in this instance an R-GAT, 393 of the TGNN model 316 may provide message passing over discovered relations with attention weights α(r) ij.

Sparsity & physics priors may include: l1 penalty for sparse graphs; anti-cycle penalty for precedence (directed acyclic graph constraint); and distance-gate prior to favor short edges. Self-supervised pretraining may include: Graph contrastive having a maximize agreement between edges in as-designed BIM and edges; inferred from scans; treat impossible edges (e.g., across floors) as hard negatives; and edge pseudo-labels if elements repeatedly co-verify in time, promote their relation weight.

In sum, the four-dimensional awareness (slack-aware gating and loss), robustness to occlusion/noise through principled visibility and temporal fusion, generalization via learned relations, and actionability through DES coupling of the disclosed techniques provide improved capabilities for classifying information of the augmented graph to determine the status of a built environment.

It should be understood that scenarios, examples, etc., described in the aforementioned examples of FIGS. 3A-3D are for illustration purposes. Accordingly, functionalities attributed to one device, such as the imaging device 140, may be performed via suitable configured components of other devices, such as the system 105 and/or computing device 160. In example, a user of the system 105 may provide natural language feedback to the imaging device 140 rather than a user of the computing device 160. In another example, the build status application 130 of the computing device 160 may cause reclassification of the terrain upon receiving new information from a user, rather than causing the imaging device 140 to reclassify the terrain based upon the associated new information.

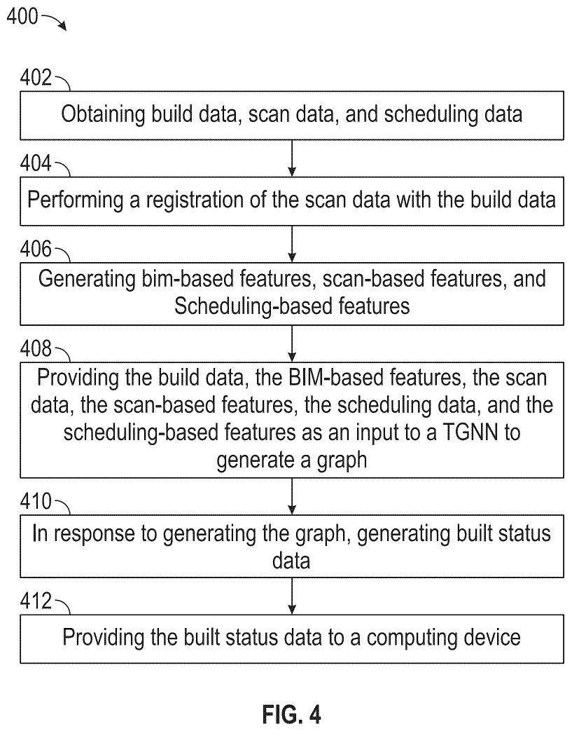

FIG. 4 is a flow diagram depicting an example computer-implemented method 400 for determining a status of a built environment using a graph neural network, in one implementation of the instant application. One or more steps of the computer-implemented method 400 may be implemented as a set of instructions stored on a computer-readable memory and executable via one or more local or remote processors (e.g., the processor 102), computing devices (e.g., the system 105, the imaging device 140, the computing device 160), and/or other electronic or electrical components, which may be in wired or wireless communication with one another.

The exemplary computer-implemented method 400 may include obtaining build data, scan data, and scheduling data (block 402). The build data may include a building information model (BIM) of the built environment. The BIM may include a plurality of elements corresponding to a plurality of physical components of the built environment, and an Industry Foundation Classes (IFC) schema indicating hierarchical relationships between the plurality of elements.

The scan data may be generated via an imaging device (e.g., the imaging device 140) during one or more scans by imaging at least a portion of the plurality of physical components of at least a portion of the built environment. At least one physical component of at least the portion of the built environment may not be fully captured by the scan data due to data incompleteness. The scan data may indicate for each of the one or more scans a pose of the imaging device and timestamp information. The data incompleteness is based upon one or more of: a characteristic of the imaging device, an environmental condition during the one or more scans, a characteristic of a physical component imaged during the one or more scans, or an occlusion of the physical component imaged during the one or more scans. The scheduling data may indicate a plurality of built tasks associated with constructing the built environment.

The computer-implemented method 400 may include performing a registration of the scan data with the build data (block 404). The registration may generate a correspondence between the plurality of physical components of the scan data and a respective at least some elements of the plurality of elements of the build data. Performing the registration (block 404) may be based upon the plurality of elements indicated in the build data, the plurality of physical components detected in the scan data, and the pose information indicated in the scan data. Performing the registration (block 404) may include preprocessing the scan data including one or more of: performing a registration of a plurality of scan datasets each generated during a respective scan of the one or more scans, cleaning the scan data, or filtering the scan data.

The computer-implemented method 400 may include generating BIM-based features, scan-based features, and scheduling-based features (block 406). The BIM-based features may indicate hierarchical relationships of the plurality of elements based upon semantics of the IFC schema of the build data. The scan-based features may indicate characteristics of the one or more scans. The scan-based features may be generated using one or more of a BaselineML model or a PointNet model. The scheduling-based features may indicate characteristics associated with performing each of the plurality of built tasks based upon the scheduling data.

The computer-implemented method 400 may include providing the build data, the BIM-based features, the scan data, the scan-based features, the scheduling data, and the scheduling-based features as an input to a temporal graph neural network (TGNN) (e.g., the TGNN model 118C), causing the TGNN to generate a graph (block 408). The graph may include a plurality of nodes and a plurality of edges. Generating the graph may include providing, by the one or more processors, the build data as an input to an IFC2VEC model (e.g., the IFC2VEC model 118A) to generate at least a portion of graph.

The TGNN may include a continuous-time architecture including dual message streams including a first messaging stream for planned construction messaging based upon the scheduling data, and a second messaging stream for actual construction messaging based upon the scan data; cross-stream gating modulated based upon slack; and a monotonic state machine head configured to enforce legal element status transitions over time.

The plurality of nodes may include a plurality of element nodes each corresponding to one element of the plurality of elements, a plurality of task nodes each corresponding to one built task of the plurality of built tasks, and a plurality of scan nodes each corresponding to one scan of the one or more scans.

The plurality of edges may each connect two nodes and each corresponding to relationship between the two nodes. The relationship between the two nodes corresponding to an edge may be selected from the group consisting of: a topological relationship based upon the hierarchical relationships indicated by the IFC schema; a spatial relationship based upon respective distances between the plurality of elements of the BIM; and a temporal relationship based upon sequential relationships indicated in the scheduling data. At least one relationship of the graph may indicate a temporal relationship.

One or more features may be applied to the plurality of nodes based upon the BIM-based features, the scan-based features, the schedule-based features, or graph-based features which may be generated based up relationships of local neighborhoods of the plurality of nodes of the graph. Generating the graph-based features may include providing the build data as an input to a BIM2GRAPH model (e.g., the BIM2GRAPH model 118B) to generate the graph-based features. Each feature applied to an element node may indicate a feature of the corresponding element, each feature applied to a task node may indicate a feature of the corresponding built task, and each feature applied to a scan node may indicate a feature of the corresponding scan. The one or more features applied to each of the plurality of nodes may include one or more of: an IFC type, a geometry hash, a discipline, a tolerance, a planned start time, a planned finish time, or slack applied to an element node; a work breakdown structure identifier, an assigned work crew, a productivity prior, a calendar, a built task start time, a built task completion time, a built task slack, or a built task precedence applied to a task node; or a timestamp, an imaging device pose, a scan modality, or a coverage mask applied to a scan node.

The graph may include one or more attributes applied to the plurality of edges. Each attribute may indicate an attribute of the corresponding relationship. The one or more attributes applied to each of the plurality of edges may include one or more of: a precedes attribute applied to an edge connecting two task nodes and indicating a precedence of each of the two corresponding tasks; an observed attribute applied to an edge connecting the element node with the scan node and indicating observability of the corresponding element in the corresponding scan; or an implements attribute applied to an edge connecting the task node with the element node and indicating the corresponding built task includes the corresponding element.

The computer-implemented method 400 may include, in response to generating the graph, generating built status data (block 410). The built status data may indicate the status of the built environment based upon analyzing the graph. The built status data may include one or more of: performing discrete-event simulation to identify one or more of a risk, a delay, or a critical path of the graph associated with the built environment; or classifying each of the plurality of elements of the built environment with a classification selected from the group consisting of: verified, deviated, missing, and no data.

The computer-implemented method 400 may include providing the built status data to a computing device (e.g., the computing device 160 via the network 110) (block 412).

In at least some implementations, the computer-implemented method 400 may include obtaining one or more of: updated scan data or updated scheduling data; providing one or more of: the updated scan data or the updated scheduling data as an input to a model causing the model to generate an updated graph; and generating updated built status data based upon the updated graph.

In some such implementations, the graph may be a dynamic four-dimensional spatio-temporal graph. The updated graph may one or more of: include at least one new edge not included in the graph before updating, or does not include at least one edge included in the graph before updating.

It should be understood that not all blocks of the exemplary flow diagram of FIG. 4 are required to be performed.

While various embodiments and/or implementations have been described, the description is intended to be exemplary, rather than limiting, and it is understood that many more embodiments and/or implementations are possible that are within the scope of the embodiments and/or implementations. Although many possible combinations of features are shown in the accompanying figures and discussed in this detailed description, many other combinations of the disclosed features are possible. Any feature of any embodiment and/or implementation may be used in combination with or substituted for any other feature or element in any other embodiment and/or implementation unless specifically restricted. Therefore, it will be understood that any of the features shown and/or discussed in the present disclosure may be implemented together in any suitable combination. Accordingly, the embodiments and/or implementations are not to be restricted except in light of the attached claims and their equivalents. Also, various modifications and changes may be made within the scope of the attached claims.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein.

Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various examples for the purpose of streamlining the disclosure. This method of disclosure is not to be interpreted as reflecting an intention that the claims require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

What is claimed is:

1. A computer-implemented method for determining a status of a built environment using a graph neural network, the computer-implemented method comprising:
obtaining, by one or more processors:
build data including a building information model (BIM) of the built environment, wherein the BIM includes a plurality of elements corresponding to a plurality of physical components of the built environment, and an Industry Foundation Classes (IFC) schema indicating hierarchical relationships between the plurality of elements;
scan data generated via an imaging device during one or more scans by imaging at least a portion of the plurality of physical components of at least a portion of the built environment, wherein:
at least one physical component of at least the portion of the built environment is not fully captured by the scan data due to data incompleteness, and
the scan data indicates for each of the one or more scans a pose of the imaging device and timestamp information; and
scheduling data indicating a plurality of built tasks associated with constructing the built environment; performing, by the one or more processors, a registration of the scan data with the build data to generate a correspondence between the plurality of physical components of the scan data and a respective at least some elements of the plurality of elements of the build data;
generating, by the one or more processors:
BIM-based features indicating hierarchical relationships of the plurality of elements based upon semantics of the IFC schema of the build data;
scan-based features indicating characteristics of the one or more scans; and
scheduling-based features indicating characteristics associated with performing each of the plurality of built tasks based upon the scheduling data;
providing, by the one or more processors, the build data, the BIM-based features, the scan data, the scan-based features, the scheduling data, and the scheduling-based features as an input to a temporal graph neural network (TGNN), causing the TGNN to:
generate a graph having:
a plurality of nodes including:
a plurality of element nodes each corresponding to one element of the plurality of elements,
a plurality of task nodes each corresponding to one built task of the plurality of built tasks, and
a plurality of scan nodes each corresponding to one scan of the one or more scans;
a plurality of edges each connecting two nodes and each corresponding to relationship between the two nodes, wherein at least one relationship of the graph indicates a temporal relationship;
one or more features applied to the plurality of nodes based upon the BIM-based features, the scan-based features, the schedule-based features, or graph-based features based up relationships of local neighborhoods of the plurality of nodes of the graph, wherein:
each feature applied to an element node indicates a feature of the corresponding element,
each feature applied to a task node indicates a feature of the corresponding built task, and
each feature applied to a scan node indicates a feature of the corresponding scan; and
one or more attributes applied to the plurality of edges, each attribute indicating an attribute of the corresponding relationship; and
in response to generating the graph, generate built status data indicating the status of the built environment based upon analyzing the graph; and
providing, by the one or more processors, the built status data to a computing device.

2. The computer-implemented method of claim 1, wherein performing the registration includes one or more of:
is based upon the plurality of elements indicated in the build data, the plurality of physical components detected in the scan data, and the pose information indicated in the scan data; or
further comprises preprocessing, by the one or more processors, the scan data including one or more of: performing a registration of a plurality of scan datasets each generated during a respective scan of the one or more scans, cleaning the scan data, or filtering the scan data.

3. The computer-implemented method of claim 1, wherein the data incompleteness is based upon one or more of: a characteristic of the imaging device, an environmental condition during the one or more scans, a characteristics of a physical component imaged during the one or more scans, or an occlusion of the physical component imaged during the one or more scans.

4. The computer-implemented method of claim 1, wherein the scan-based features are generated using one or more of a BaselineML model or a PointNet model.

5. The computer-implemented method of claim 1, wherein the relationship between the two nodes corresponding to an edge is selected from the group consisting of: a topological relationship based upon the hierarchical relationships indicated by the IFC schema; a spatial relationship based upon respective distances between the plurality of elements of the BIM; and a temporal relationship based upon sequential relationships indicated in the scheduling data.

6. The computer-implemented method of claim 1, wherein the one or more features applied to each of the plurality of nodes include one or more of:
an IFC type, a geometry hash, a discipline, a tolerance, a planned start time, a planned finish time, or slack applied to an element node;
a work breakdown structure identifier, an assigned work crew, a productivity prior, a calendar, a built task start time, a built task completion time, a built task slack, or a built task precedence applied to a task node; or
a timestamp, an imaging device pose, a scan modality, or a coverage mask applied to a scan node.

7. The computer-implemented method of claim 1, wherein the one or more attributes applied to each of the plurality of edges include one or more of:
a precedes attribute applied to an edge connecting two task nodes and indicating a precedence of each of the two corresponding tasks;
an observed attribute applied to an edge connecting the element node with the scan node and indicating observability of the corresponding element in the corresponding scan; or
an implements attribute applied to an edge connecting the task node with the element node and indicating the corresponding built task includes the corresponding element.

8. The computer-implemented method of claim 1, wherein the TGNN includes:
a continuous-time architecture including dual message streams including a first messaging stream for planned construction messaging based upon the scheduling data, and a second messaging stream for actual construction messaging based upon the scan data;
cross-stream gating modulated based upon slack; and
a monotonic state machine head configured to enforce legal element status transitions over time.

9. The computer-implemented method of claim 1, further comprising:
obtaining, by the one or more processors, one or more of: updated scan data or updated scheduling data;
providing, by the one or more processors, one or more of: the updated scan data or the updated scheduling data as an input to a model causing the model to generate an updated graph; and
generating, by the one or more processors, updated built status data based upon the updated graph.

10. The computer-implemented method of claim 9, wherein:
the graph is a dynamic four-dimensional spatio-temporal graph; and
the updated graph one or more of includes at least one new edge not included in the graph before updating, or does not include at least one edge included in the graph before updating.

11. The computer-implemented method of claim 1, wherein generating the built status data includes one or more of:
performing, by the one or more processors via the TGNN, discrete-event simulation to identify one or more of a risk, a delay, or a critical path of the graph associated with the built environment; or
classifying, by the one or more processors via the TGNN, each of the plurality of elements of the built environment with a classification selected from the group consisting of: verified, deviated, missing, and no data.

12. The computer-implemented method of claim 1, wherein generating the graph comprises providing, by the one or more processors, the build data as an input to an IFC2VEC model to generate at least a portion of graph.

13. The computer-implemented method of claim 1, wherein generating the graph-based features comprises providing, by the one or more processors, the build data as an input to a BIM2GRAPH model to generate the graph-based features.

14. A system for determining a status of a built environment using a graph neural network, the system comprising:
one or more processors; and
one or more memories having stored thereon processor-executable instructions that, when executed by the one or more processors, cause the one or more processors to:
obtain:
build data including a building information model (BIM) of the built environment, wherein the BIM includes a plurality of elements corresponding to a plurality of physical components of the built environment, and an Industry Foundation Classes (IFC) schema indicating hierarchical relationships between the plurality of elements;
scan data generated via an imaging device during one or more scans by imaging at least a portion of the plurality of physical components of at least a portion of the built environment, wherein:
at least one physical component of at least the portion of the built environment is not fully captured by the scan data due to data incompleteness, and
the scan data indicates for each of the one or more scans a pose of the imaging device and timestamp information; and
scheduling data indicating a plurality of built tasks associated with constructing the built environment;
perform a registration of the scan data with the build data to generate a correspondence between the plurality of physical components of the scan data and a respective at least some elements of the plurality of elements of the build data;
generate:
BIM-based features indicating hierarchical relationships of the plurality of elements based upon semantics of the IFC schema of the build data;
scan-based features indicating characteristics of the one or more scans; and
scheduling-based features indicating characteristics associated with performing each of the plurality of built tasks based upon the scheduling data;
provide the build data, the BIM-based features, the scan data, the scan-based features, the scheduling data, and the scheduling-based features as an input to a temporal graph neural network (TGNN), causing the TGNN to:
generate a graph having:
a plurality of nodes including:
a plurality of element nodes each corresponding to one element of the plurality of elements,
a plurality of task nodes each corresponding to one built task of the plurality of built tasks, and
a plurality of scan nodes each corresponding to one scan of the one or more scans;
a plurality of edges each connecting two nodes and each corresponding to relationship between the two nodes, wherein at least one relationship of the graph indicates a temporal relationship;
one or more features applied to the plurality of nodes based upon the BIM-based features, the scan-based features, the schedule-based features, or graph-based features based up relationships of local neighborhoods of the plurality of nodes of the graph, wherein:
each feature applied to an element node indicates a feature of the corresponding element,
each feature applied to a task node indicates a feature of the corresponding built task, and
each feature applied to a scan node indicates a feature of the corresponding scan; and
one or more attributes applied to the plurality of edges, each attribute indicating an attribute of the corresponding relationship;
in response to generating the graph, generate built status data indicating the status of the built environment based upon analyzing the graph; and
provide the built status data to a computing device.

15. The system of claim 14, wherein to perform the registration incudes one or more of:
is based upon the plurality of elements indicated in the build data, the plurality of physical components detected in the scan data, and the pose information indicated in the scan data; or
the one or more memories further comprising instructions that, when executed by the one or more processors, cause the one or more processors to:
preprocess the scan data including one or more of: performing a registration of a plurality of scan datasets each generated during a respective scan of the one or more scans, cleaning the scan data, or filtering the scan data.

16. The system of claim 14, wherein the relationship between the two nodes corresponding to an edge is selected from the group consisting of: a topological relationship based upon the hierarchical relationships indicated by the IFC schema; a spatial relationship based upon respective distances between the plurality of elements of the BIM; and a temporal relationship based upon sequential relationships indicated in the scheduling data.

17. The system of claim 14, wherein one or more of:
the one or more features applied to each of the plurality of nodes include one or more of:
an IFC type, a geometry hash, a discipline, a tolerance, a planned start time, a planned finish time, or slack applied to an element node;
a work breakdown structure identifier, an assigned work crew, a productivity prior, a calendar, a built task start time, a built task completion time, a built task slack, or a built task precedence applied to a task node; or
a timestamp, an imaging device pose, a scan modality, or a coverage mask applied to a scan node; or
the one or more attributes applied to each of the plurality of edges include one or more of:
a precedes attribute applied to an edge connecting two task nodes and indicating a precedence of each of the two corresponding tasks;
an observed attribute applied to an edge connecting the element node with the scan node and indicating observability of the corresponding element in the corresponding scan; or
an implements attribute applied to an edge connecting the task node with the element node and indicating the corresponding built task includes the corresponding element.

18. The system of claim 14, wherein the TGNN includes:
a continuous-time architecture including dual message streams including a first messaging stream for planned construction messaging based upon the scheduling data, and a second messaging stream for actual construction messaging based upon the scan data;
cross-stream gating modulated based upon slack; and
a monotonic state machine head configured to enforce legal element status transitions over time.

19. The system of claim 14, wherein:
the graph is a dynamic four-dimensional spatio-temporal graph; and
based upon receiving update scheduling data or updated scan data causing an update to the graph, the graph generates at least one new edge or causes at least one edge to be removed from the graph.

20. A non-transitory computer-readable medium storing processor-executable instructions that, when executed by one or more processors, cause the one or more processors to at least:
obtain:
build data including a building information model (BIM) of a built environment, wherein the BIM includes a plurality of elements corresponding to a plurality of physical components of the built environment, and an Industry Foundation Classes (IFC) schema indicating hierarchical relationships between the plurality of elements;
scan data generated via an imaging device during one or more scans by imaging at least a portion of the plurality of physical components of at least a portion of the built environment, wherein:
at least one physical component of at least the portion of the built environment is not fully captured by the scan data due to data incompleteness, and
the scan data indicates for each of the one or more scans a pose of the imaging device and timestamp information; and
scheduling data indicating a plurality of built tasks associated with constructing the built environment;
perform a registration of the scan data with the build data to generate a correspondence between the plurality of physical components of the scan data and a respective at least some elements of the plurality of elements of the build data;
generate:
BIM-based features indicating hierarchical relationships of the plurality of elements based upon semantics of the IFC schema of the build data;
scan-based features indicating characteristics of the one or more scans; and
scheduling-based features indicating characteristics associated with performing each of the plurality of built tasks based upon the scheduling data;
provide the build data, the BIM-based features, the scan data, the scan-based features, the scheduling data, and the scheduling-based features as an input to a temporal graph neural network (TGNN), causing the TGNN to:
generate a graph having:
a plurality of nodes including:
a plurality of element nodes each corresponding to one element of the plurality of elements,
a plurality of task nodes each corresponding to one built task of the plurality of built tasks, and
a plurality of scan nodes each corresponding to one scan of the one or more scans;
a plurality of edges each connecting two nodes and each corresponding to relationship between the two nodes, wherein at least one relationship of the graph indicates a temporal relationship;
one or more features applied to the plurality of nodes based upon the BIM-based features, the scan-based features, the schedule-based features, or graph-based features based up relationships of local neighborhoods of the plurality of nodes of the graph, wherein:
each feature applied to an element node indicates a feature of the corresponding element,
each feature applied to a task node indicates a feature of the corresponding built task, and
each feature applied to a scan node indicates a feature of the corresponding scan; and
one or more attributes applied to the plurality of edges, each attribute indicating an attribute of the corresponding relationship; and
in response to generating the graph, generate built status data indicating a status of the built environment based upon analyzing the graph; and
provide the built status data to a computing device.
